(19) United States
(12) Patent Application Publication
(10) Pub. No.: US 2018/0012872 A1
(43) Pub. Date: Jan. 11, 2018

(54) MOLDED LED PACKAGE WITH LAMINATED LEADFRAME AND METHOD OF MAKING THEREOF

(71) Applicant: GLO AB, Lund (SE)

(72) Inventors: Kazunori OKUI, Newark, CA (US); Sheng-Min WANG, Taipei (TW); Hui-Yu HUANG, Taipei (TW)

(21) Appl. No.: 15/641,866

(22) Filed: Jul. 5, 2017

Related U.S. Application Data
(60) Provisional application No. 62/358,920, filed on Jul. 6, 2016.

(51) Int. Cl. H01L 25/075; H01L 33/52; H01L 33/60; H01L 33/62

(52) U.S. Cl. CPC H01L 25/0753; H01L 33/62; H01L 33/52; H01L 33/60; H01L 2933/0066

(57) ABSTRACT

A method of packaging light emitting diodes (LEDs) includes molding a lead frame containing a plurality of lead frame fingers that are parallel to each other such that the lead frame fingers are separated from each other by a molded insulating structure to form a molded lead frame, mounting light emitting diodes to at least a portion of the molded lead frame, and dicing the molded lead frame to form a plurality of lead-containing mounting structures. Each of the lead-containing mounting structure includes a respective plurality of leads that are remaining portions of the lead frame, and each of the plurality of leads contains at least one castellation.

### RELATED APPLICATIONS

This application claims benefit of priority of U.S. Provisional Application No. 62/358,920, filed Jul. 6, 2016, the entire contents of all of which are incorporated herein by reference.

### FIELD

The embodiments of the invention are directed generally to packaged light emitting diode (LED) devices and methods of packaging LED devices.

### BACKGROUND

Light emitting diodes (LEDs), such as nanowire LEDs, have a variety of uses, including in electronic displays, such as liquid crystal displays in laptops or LED televisions. In a typical LED packaging process, a semiconductor die containing one or more LEDs is mounted to a lead frame, and the die and lead frame are encased in a protective mold. The mold may include an open region aligned with the LED that enables light to be emitted from the LED. Electrical connections to the LED package may be made via the lead frame.

It is difficult to shrink the package size because of requirement of enhancing structure of the molded panel. Thus, further improvement of package structure is desired.

### SUMMARY

According to an aspect of the present disclosure, a method of packaging light emitting diodes (LEDs) includes molding a lead frame containing a plurality of lead frame fingers that are parallel to each other such that the lead frame fingers are separated from each other by a molded insulating structure to form a molded lead frame, mounting light emitting diodes to at least a portion of the molded lead frame, and dicing the molded lead frame to form a plurality of lead-containing mounting structures. Each of the lead-containing mounting structure includes a respective plurality of leads that are remaining portions of the lead frame, and each of the plurality of leads contains at least one castellation.

According to another aspect of the present disclosure, a light emitting diode assembly comprises a lead-containing mounting structure comprising a plurality of castellation containing leads separated by a reflective insulating structure along a first direction and having a planar top surface and sidewalls contained within a pair of planes that extend along the first direction, a plurality of light emitting diodes mounted on the plurality of leads, wherein two nodes of each of the light emitting diodes are electrically shorted to a respective pair of leads within the plurality of leads, and a transparent encapsulation structure embedding the plurality of light emitting diodes.

According to an aspect of the present disclosure, a method of packaging a light emitting diode (LED) is provided, which comprises steps of: bonding a lead frame to a layer stack of an insulating substrate and a metal sheet; patterning the metal sheet into metal plates; forming a via cavity through each metal plate into the insulating substrate, wherein a surface of a respective lead frame is exposed at an end of each via cavity; forming a prototype castellation comprising a metal within each via cavity; dicing an assembly including the lead frame, the insulating substrate, and the prototype castellations to form a plurality of lead-containing mounting structures, wherein each of the lead-containing mounting structure includes a respective plurality of leads that are remaining portions of the lead frame; and mounting light emitting diodes to one of the lead-containing mounting structures. .

According to another aspect of the present disclosure, a light emitting diode assembly is provided, which comprises: a lead-containing mounting structure including a plurality of leads located on a surface of an insulating matrix and a plurality of castellations partially embedded within the insulating matrix, wherein each of the leads has a shape of a rectangular parallelepiped, and wherein each of the castellations have a convex sidewall contacting the insulating matrix and a planar surface that is not in physical contact with the insulating matrix; a plurality of light emitting diodes mounted on the plurality of leads, wherein two nodes of each of the light emitting diodes are electrically shorted to a respective pair of leads within the plurality of leads; and a transparent encapsulation structure embedding the plurality of light emitting diodes and mounted on the lead-containing mounting structure.

Various embodiments include methods of packaging a light emitting diode (LED) that include providing a lead frame comprising a first lead having a first recess in a bottom surface and a second lead having a second recess in a bottom surface, placing a LED die over a top surface of at least one of the first and the second leads, electrically connecting the LED die to the first lead and to the second lead, forming a package around the LED die, the first lead and the second lead, the package having an opening in its upper surface exposing at least the LED die, and separating the package containing the LED die, the first lead and the second lead from the lead frame such that the package contains a first castellation and a second castellation in a side surface of the package, wherein the first castellation exposes at least one of the first lead and a first platable metal which is electrically connected to the first lead, the second castellation exposes at least one of the second lead and a second platable metal which is electrically connected to the second lead.

Further embodiments include methods of packaging a light emitting diode (LED) that include providing a lead frame comprising a first lead and a second lead, placing a LED die over a top surface of at least one of the first and the second leads, electrically connecting the LED die to the first lead and to the second lead, forming a package around the LED die, the first lead and the second lead, the package having an opening in its upper surface exposing at least the LED die, and separating the package containing the LED die, the first lead and the second lead from the lead frame, wherein the lead frame contains a first alignment mark and the package contains a second alignment mark.

Further embodiments include methods of packaging light emitting diodes (LEDs) that include bonding a plurality of LED die over a plurality of leads of a lead frame, electrically connecting each of the plurality of LED die to a respective two of the plurality of leads, dipping the lead frame into a mold containing a moldable material, solidifying the moldable material to form a panel comprising a plurality of moldable material packages attached to the lead frame, wherein each of the plurality of packages is located around at least one of the plurality of LED dies electrically connected to the respective two of the plurality of leads, attaching a first set of the plurality of packages to a dicing tape, and singulating the first set of the plurality of packages from the panel.

Further embodiments include methods of testing a packaged light emitting diode (LED) that include providing a package containing a LED die which is electrically connected to a first lead and to a second lead located in the package, wherein the LED die is located over a top surface of at least one of the first and the second leads, attaching a bottom surface of the package to dicing tape such that a first recess is located in a bottom surface of the first lead exposed in the bottom surface of the package and a second recess is located in a bottom surface of the second lead exposed in the bottom surface of the package, and testing the LED die by poking a testing pin or needle through the dicing tape into at least one of the first recess and the second recess.

Various embodiments include packaged light emitting diode (LED) devices that include a first lead having a first recess in a bottom surface, a second lead having a second recess in a bottom surface, a LED die located over a top surface of at least one of the first and the second leads and electrically connected to the first lead and to the second lead, and a package located around the LED die, the first lead and the second lead, wherein the package contains an opening in its upper surface exposing at least the LED die, and the package contains a first castellation and a second castellation in a side surface of the package, the first castellation exposes at least one of the first lead and a first platable metal which is electrically connected to the first lead, and the second castellation exposes at least one of the second lead and a second platable metal which is electrically connected to the second lead.

Further embodiments include packaged light emitting diode (LED) devices that include a first lead having a first recess in a bottom surface, a second lead having a second recess in a bottom surface, a LED die located over a top surface of at least one of the first and the second leads and electrically connected to the first lead and to the second lead, a package located around the LED die, the first lead and the second lead, and wherein a sidewall of the package has a non-uniform thickness and contains at least one structural strength enhancing region of increased thickness.

Further embodiments include packaged light emitting diode (LED) devices that include a first lead having a first recess in a bottom surface, a second lead having a second recess in a bottom surface, a LED die located over a top surface of at least one of the first and the second leads and electrically connected to the first lead and to the second lead, a package located around the LED die, the first lead and the second lead, and wherein sides and ends of the first and the second leads are etched to increase a surface area of the first and the second leads.

Further embodiments include a lead frame including a frame connected to a plurality of electrically conductive leads, wherein at least one of the plurality of leads comprises a floating finger lead which contains at least one free hanging, cantilevered end which is not attached to the frame.

### BRIEF DESCRIPTION OF THE DRAWINGS

The accompanying drawings, which are incorporated herein and constitute part of this specification, illustrate example embodiments of the invention, and together with the general description given above and the detailed description given below, serve to explain the features of the invention.

FIG. 1 is a schematic perspective illustration of a packaged LED device according to an embodiment.

FIG. 2A illustrates the packaged LED device mounted in a top-emitting configuration.

FIG. 2B illustrates the packaged LED device mounted in a side-emitting configuration.

FIG. 3A illustrates a packaged LED device according to one embodiment in which the package includes multiple LED dies and an interior wall separating a first compartment containing the at least one first LED die from a second compartment containing at least one second LED die.

FIG. 3B illustrates a packaged LED device according to another embodiment in which a sidewall of the package has a non-uniform thickness and contains structural strength enhancing regions of increased thickness.

FIG. 3C illustrates a packaged LED device according to another embodiment in which the package includes multiple LED dies and an interior wall separating a first compartment containing a green emitting LED die and a first encapsulant containing a green phosphor located over the green emitting LED die from a second compartment containing a red emitting LED die and a blue emitting LED die and a second encapsulant which lacks the green phosphor located over the red emitting LED die and the blue emitting LED die.

FIG. 3D illustrates a packaged LED device according to another embodiment in which the package includes multiple LED dies and two interior walls defining three separate compartments, where each compartment contains at least one LED die.

FIG. 4A illustrates a portion of a lead frame according to one embodiment in which the respective leads contain non-uniform recesses for forming castellations having varying widths and sides and ends of the leads are etched to increase a surface area of the leads.

FIG. 4B illustrates a portion of a lead frame that includes floating finger leads which contain at least one free hanging, cantilevered end which is not attached to the frame.

FIGS. 5A-D illustrate a method of packaging an LED die with a plurality of leads and a package according to one embodiment.

FIG. 6 illustrates a lead frame having a plurality of molded packages attached thereto and having alignment marks to facilitate separation of individual LED packages.

FIG. 7 schematically illustrates a method of testing an LED package using a testing pin according to one embodiment.

FIG. 8A is a top-down schematic view of a lead frame according to an embodiment of the present disclosure.

FIG. 8B is a vertical cross-sectional view of the lead frame of FIG. 8A overlying a layer stack of an insulating substrate and a metal sheet according to an embodiment of the present disclosure.

FIG. 9 is a vertical cross-sectional view of the exemplary structure after formation of a bonded assembly of the lead frame, the insulating substrate, and the metal sheet according to an embodiment of the present disclosure.

FIG. 10A is a vertical cross-sectional view of the exemplary structure after patterning the metal sheet into discrete metal plates according to an embodiment of the present disclosure.

FIG. 10B is a bottom view of the exemplary structure of FIG. 10A.

FIG. 11A is a vertical cross-sectional view of the exemplary structure after formation of via cavities through the metal plates and the insulating substrate according to an embodiment of the present disclosure.

FIG. 11B is a bottom view of the exemplary structure of FIG. 11A.

FIG. 12A is a vertical cross-sectional view of the exemplary structure after formation of castellations through the via cavities according to an embodiment of the present disclosure.

FIG. 12B is a bottom view of the exemplary structure of FIG. 12A.

FIG. 12C is a vertical cross-sectional view of a first alternative embodiment of the exemplary structure at the processing step of FIG. 12B.

FIG. 12D is a vertical cross-sectional view of a second alternative embodiment of the exemplary structure at the processing step of FIG. 12C.

FIG. 13A is a top-down view of the exemplary structure during dicing that divides the exemplary structure into a plurality of mounting structures according to an embodiment of the present disclosure.

FIG. 13B is a bottom view of the exemplary structure of FIG. 13A.

FIG. 14A is a perspective view of an LED assembly including a mounting structure, LEDs bonded to the leads in the mounting structure, and a transparent encapsulation structure according to an embodiment of the present disclosure.

FIG. 14B is a perspective view of an alternate embodiment of the LED assembly of FIG. 14B.

FIG. 15A is a top-down schematic view of an exemplary structure after formation of a bonded assembly of the lead frame and an insulating substrate according to an embodiment of the present disclosure.

FIG. 15B is a vertical cross-sectional view along the plane B-B′ of FIG. 15A.

FIG. 15C is a vertical cross-sectional view along the plane C-C′ of FIG. 15A.

FIG. 15D is a vertical cross-sectional view along the plane D-D′ of FIG. 15A.

FIG. 15E is a vertical cross-sectional view along the plane E-E′ of FIG. 15A.

FIG. 16A is a top-down schematic view of the exemplary structure from FIGS. 15A-15E during dicing according to an embodiment of the present disclosure.

FIG. 16B is a vertical cross-sectional view along the plane B-B′ of FIG. 16A.

FIG. 16C is a vertical cross-sectional view along the plane C-C′ of FIG. 16A.

FIG. 16D is a vertical cross-sectional view along the plane D-D′ of FIG. 16A.

FIG. 16E is a vertical cross-sectional view along the plane E-E′ of FIG. 16A.

FIG. 17 is an exploded view of a mounting structure formed by dicing.

FIG. 18A is a perspective view of an LED assembly including a mounting structure, LEDs bonded to the leads in the mounting structure, and a transparent encapsulation structure according to an embodiment of the present disclosure.

FIG. 18B is a perspective view of an alternate embodiment of the LED assembly of FIG. 18A.

FIGS. 19 and 20 are an exploded three dimensional view and a perspective three dimensional view, respectively, of a structure of an alternative embodiment.

FIG. 21 is a perspective three dimensional view of a structure of the alternative embodiment of FIGS. 19 and 20 during fabrication.

### DETAILED DESCRIPTION

The various embodiments will be described with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Embodiments of the invention include packaged LED devices and methods of packaging an LED. In various embodiments, a package and lead design includes features that enable the packaged LED device to be mounted as either a top-emitting or a side-emitting LED package.

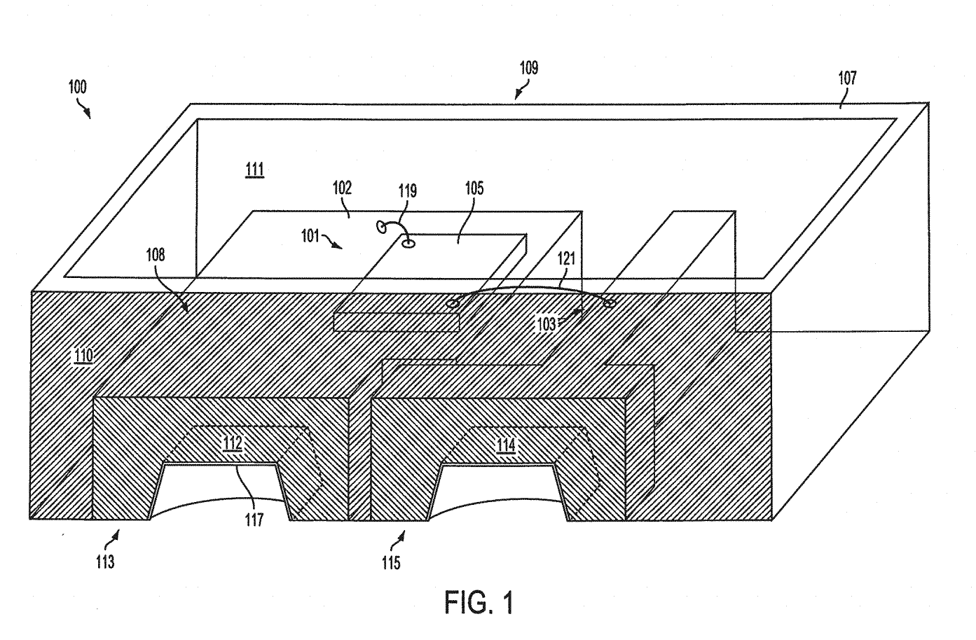

FIG. 1 is a schematic perspective illustration of a packaged LED device 100 according to one embodiment. The packaged LED device 100 includes a plurality of leads, including a first lead 101 and a second lead 103. Each lead 101, 103 may be formed of an electrically conductive material (e.g., a metal, such as copper). The leads 101, 103 may be formed as part of a lead frame and separated from the frame to produce individual packaged LED devices 100, as described below. The leads 101, 103 may extend generally parallel without contacting one another between a first side surface 108 and a second side surface 109 of the device 100.

At least one LED die 105 (e.g., chip) may be mounted on a first surface 102 of lead 101. The LED die 105 may include one or more light-emitting semiconductor elements on a supporting substrate. Any suitable LED structure may be utilized. In embodiments, the LED may be a nanowire-based LED. Nanowire LEDs are typically based on one or more pn- or pin-junctions. Each nanowire may comprise a first conductivity type (e.g., doped n-type) nanowire core and an enclosing second conductivity type (e.g., doped p-type) shell for forming a pn or pin junction that in operation provides an active region for light generation. An intermediate active region between the core and shell may comprise a single intrinsic or lightly doped (e.g., doping level below 10¹⁶ cm⁻³) semiconductor layer or one or more quantum wells, such as 3-10 quantum wells comprising a plurality of semiconductor layers of different band gaps. Nanowires are typically arranged in arrays comprising hundreds, thousands, tens of thousands, or more, of nanowires side by side on the supporting substrate to form the LED structure. The nanowires may comprise a variety of semiconductor materials, such as III-V semiconductors and/or III-nitride semiconductors, and suitable materials include, without limitation GaAs, InAs, Ge, ZnO, InN, GaInN, GaN, AlGaInN, BN, InP, InAsP, GaInP, InGaP:Si, InGaP:Zn, GalnAs, AlInP, GaAlInP, GaAlInAsP, GaInSb, InSb, AN, GaP and Si. The supporting substrate may include, without limitation, III-V or II-VI semiconductors, Si, Ge, Al₃O₃, SiC, Quartz and glass. Further details regarding nanowire LEDs and methods of fabrication are discussed, for example, in U.S. Pat. Nos. 7,396,696, 7,335,908 and 7,829,443, PCT Publication Nos. WO2010014032, WO2008048704 and WO2007102781, and in Swedish patent application SE 1050700-2, all of which are incorporated by reference in their entirety herein. Alternatively, bulk (i.e., planar layer type) LEDs may be used instead of or in addition to the nanowire LEDs.

The LED die 105 may be mounted to the first surface 102 of the lead 101 using any suitable bonding technique. In embodiments, the surface of the LED die 105 may be electrically insulated from the lead 101 via an insulating material (e.g., a sapphire layer), which may be or may form part of the support substrate of the die 105. The active region of the LED die 105 may be electrically connected to the first lead 101 by a first wire 119, which may be bonded to a first bond pad region of the die 105. A second wire 121 may be bonded to a second bond pad region of the die 105 to electrically connect the die 105 to the second lead 103.

The packaged LED device 100 also includes a package 107, which may be a protective mold around the die 105 and leads 101, 103. For clarity, the package 107 is shown as transparent in FIG. 1. In embodiments, the package 107 may be a molded epoxy material, although other materials (e.g., ceramic, plastic, glass, etc.) may be utilized. The leads 101, 103 may be at least partially embedded in the package 107. As shown in FIG. 1, the package 107 may form the sidewalls and at least a portion of the bottom surface of the device 100 and may include an opening 111 in its upper surface exposing at least the LED die 105. In some embodiments, the opening 111 may be filled with an encapsulant material (not shown) that is optically transmissive over at least a selected wavelength range. The encapsulant may comprise a phosphor or dye material.

The leads 101, 103 may each include a recessed portion 112, 114 on a bottom surface of the respective leads 101, 103 (i.e., on the surface opposite the LED die 105). The package 107 may include a first castellation 113 and a second castellation 115 in a side surface 110 of the package 107. The first castellation 113 exposes an edge of the first lead 101 including the recessed portion 112. The second castellation 115 exposes an edge of the second lead 103 including the recessed portion 114. Each of the recessed portions 112, 114 may include a filler material 117, which may be a platable metal formed over the recessed portions 112, 114. Thus, in an embodiment, the first castellation 113 exposes an edge of the first lead 101 and platable metal 117, and the second castellation 115 exposes an edge of the second lead 103 and the platable metal 117.

In the embodiment of FIG. 1, the leads 101, 103 have non-uniform dimensions along their length between the first end 108 and the second end 109 of the device 100. As shown in FIG. 1, the cross-sectional dimensions of the leads 101, 103 are identical proximate the first end 108, including in the portions containing the respective recessed portions 112, 114, but are different proximate to the second end 108 of the device. The first lead 101 has an “L” shape in which the width of the lead 101 increases to accommodate the LED die 105. The second lead 103 is widest proximate to the first end 108, and narrows proximate to the second end 109. Various other configurations are possible, including where the leads 101, 103 have identical shapes along their entire lengths. Preferably, the LED die 105 is bonded to only to the top surface 102 of a rear portion of the first lead 101, the first recess 112 is located in the bottom surface in a front portion of the first lead 101 which is different from the rear portion of the first lead, and the second recess 114 is located in the bottom surface in a front portion of the second lead 103 which is wider than rear portion of the second lead.

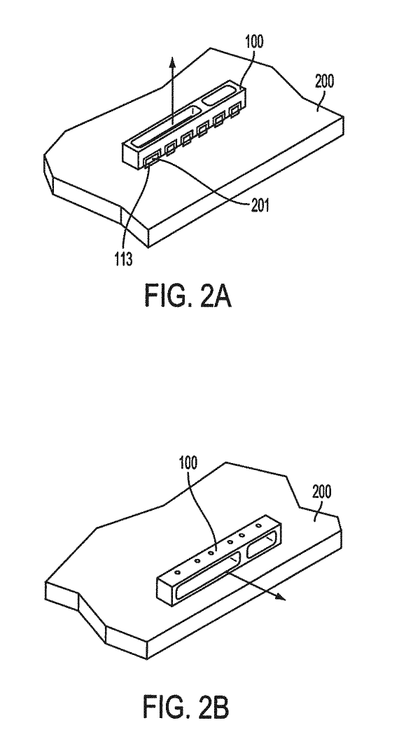

The packaged LED device 100 may be mounted to a support surface 200 in either a top-emitting or a side-emitting configuration, as shown in FIGS. 2A-B. FIG. 2A shows the device 100 in a top-emitting configuration, with the predominant direction of light emission from the LED indicated by the vertical arrow. At least a portion of the leads 101, 103, including at least the recessed portions 112, 114, may be exposed on the bottom surface of the package 107. Electrical contacts 201 located over the support surface 200 may contact the exposed portions of the respective leads 101, 103 to connect the leads 101, 103 and the LED die 105 to an external current/voltage source. In embodiments, the electrical contacts 201 may be bonded to the leads 101, 103, such as via soldering. In some embodiments, the electrical contacts 201 may be soldered to the optional filler material 117 that may be located within the recessed portions 112, 114 of the leads 101, 103.

FIG. 2B shows the device 100 in a side-emitting configuration, in which the side surface 110 of the package 107 containing the castellations 113, 115 (see FIG. 1) faces the support structure 200 and the predominant direction of light emission (as indicated by the arrow) is parallel to the support surface 200. In this configuration, the electrical contacts 201 on the support structure 200 (not visible in this view) contact the first and second leads 101, 103 through the first and second castellations 113, 115, respectively. As in the embodiment of FIG. 2A, the electrical contacts 201 may be bonded (e.g., soldered) to the leads, either directly or indirectly through the optional filler material. The side-emitting configuration of FIG. 2B may provide improved coupling of light into a waveguide.

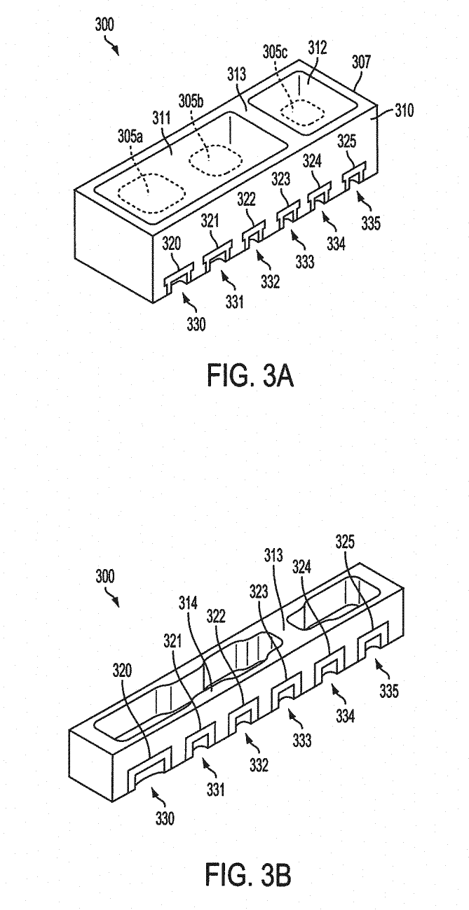

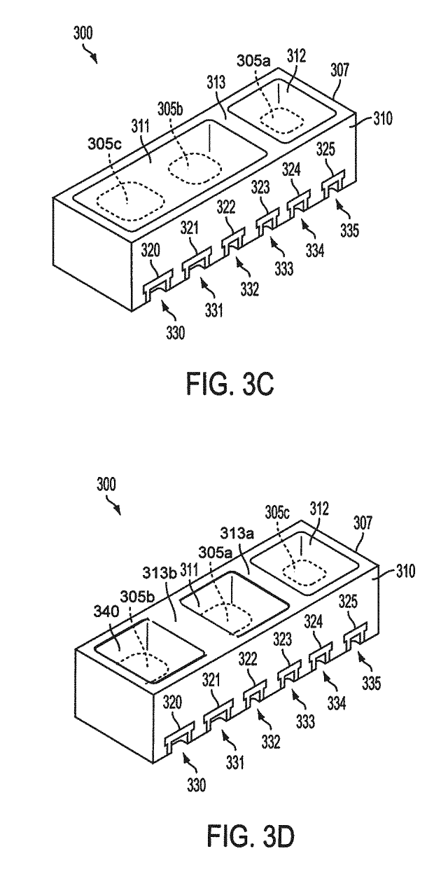

The embodiment of FIG. 1 illustrates a package for a single LED die. In other embodiments, multiple LED dies may be included within a package. FIG. 3A illustrates an embodiment of a packaged LED device 300 in which the package 307 includes multiple LED dies 305a, 305b, 305c and an interior wall 313 separating a first compartment 311 containing LED dies 305a, 305b from a second compartment 312 containing LED die 305c. Each of the LED dies 305a, 305b, 305c may be configured to emit light at different wavelengths (e.g., green, blue and red visible light). The packaged LED device 300 may include a plurality of leads 320, 321, 322, 323, 324, 325, each having a recessed portion as described above in connection with FIG. 1. Each of the dies 305a, 305b, 305c may be mounted on a top surface of a lead and electrically connected to at least two different leads, as described above. The package 307 may include castellations 330, 331, 332, 333, 334, 335, 336 on a side surface 310 of the package 307 that expose the edges of the leads 320, 321, 322, 323, 324, 325 at their respective recessed portions.

In one embodiment, the interior wall 313 may separate the second compartment 312 containing a red-emitting LED die 305c from the first compartment 311 containing a green-emitting LED die 305a and a blue-emitting LED die 305b. The second compartment 312 may contain a first encapsulant (not shown) containing a red emitting phosphor located over the red LED die 305c, and the first compartment 311 may contain a second encapsulant (not shown) which lacks the red emitting phosphor located over the green-emitting LED die 305a and the blue-emitting LED die 305b. Each die may contain nanowire and/or bulk LEDs. For example, the green emitting die 305a may comprise nanowire LEDs, the red emitting die 305c may comprise bulk LEDs, and the blue emitting die 305b may comprise either nanowire or bulk LEDs.

FIG. 3B illustrates an alternative embodiment of the packaged LED device 300 in which the package 307 includes a variable wall thickness and an internal radius to add wall thickness in select areas and thus increase the package structural strength, such as a structural strength enhancing region 314 of increased thickness in a sidewall of the package. FIG. 3B also illustrates castellations 330, 331, 332, 333, 334, 335 and leads 320, 321, 322, 323, 324, 325 having varying dimensions (e.g., at castellation 330 and lead 320 are wider than the other castellations and leads in the device 300).

FIG. 3C illustrates another embodiment of a packaged LED device 300. The device 300 may be similar to the device of FIG. 3A, but in this embodiment, the second compartment 312 separated by the interior wall 313 contains a green-emitting LED die 305a, and the first compartment 311 contains a blue-emitting LED die 305b and a red-emitting LED die 305c. The second compartment 312 may contain a first encapsulant (not shown) containing a green-emitting phosphor located over the green-emitting LED die 305a, and the first compartment 311 may contain a second encapsulant (not shown) which lacks the green emitting phosphor over the blue-emitting LED die 305a and the red-emitting LED die 305c. Each die may contain nanowire and/or bulk LEDs. In addition, the LED device 300 of FIG. 3C may include a variable wall thickness and internal radius to enhance structural strength and/or castellations 330, 331, 332, 333, 334, 335 having varying dimensions such as shown in FIG. 3B.

FIG. 3D illustrates yet another embodiment of a packaged LED device. The device 300 may be similar to the devices shown in FIGS. 3A and 3C, but may include two interior walls 313a, 313b that separate the device 300 into three compartments 311, 312, 340. Each compartment 311, 312, 340 may contain at least one LED die 305a, 305b, 305c. For example, compartment 340 may contain a first one of a blue-emitting LED die 305b, a green-emitting LED die 305a, and a red-emitting LED die 305c (e.g., compartment 340 contains a blue-emitting LED die 305b in FIG. 3D), compartment 311 may contain a second one of the blue-emitting LED die 305b, the green-emitting LED die 305a and the red-emitting LED die 305c (e.g., compartment 311 contains a green-emitting LED die 305a in FIG. 3D), and compartment 312 may contain a third one of the blue-emitting LED die 305b, the green-emitting LED die 305a and the red-emitting LED die 305c (e.g., compartment 312 contains a red-emitting LED die 305c in FIG. 3D).

Each compartment 311, 312, 340 may contain an encapsulant (not shown) over the respective LED dies 305a, 305b, 305c. The encapsulant in each compartment 311, 312, 340 may be the same as or different than the encapsulant in the other compartments. In one embodiment, compartment 312 may contain a first encapsulant (not shown) containing a red emitting phosphor located over the red LED die 305c, compartment 311 may contain a second encapsulant (not shown) which lacks the red emitting phosphor located over the green-emitting LED die 305a, and compartment 340 may contain a third encapsulant (not shown) which lacks the red emitting phosphor located over the blue-emitting LED die 305b. The second encapsulant and the third encapsulant may be the same material or different materials.

In another embodiment, compartment 311 may contain a first encapsulant (not shown) containing a green emitting phosphor located over the green LED die 305a, compartment 312 may contain a second encapsulant (not shown) which lacks the green-emitting phosphor located over the red-emitting LED die 305c, and compartment 340 may contain a third encapsulant (not shown) which lacks the green-emitting phosphor located over the blue-emitting LED die 305b. The second encapsulant and the third encapsulant may be the same material or different materials in this embodiment.

In yet another embodiment, compartment 311 may contain a first encapsulant (not shown) containing a green emitting phosphor located over the green LED die 305a, compartment 312 may contain a second encapsulant (not shown) containing a red emitting phosphor located over the red LED die 305c, and compartment 340 may contain a third encapsulant (not shown) which lacks the green-emitting phosphor and the red-emitting phosphor located over the blue-emitting LED die 305b.

Each die in the respective compartments 311, 312, 340 may contain nanowire and/or bulk LEDs. Further, a packaged LED device 300 may include additional interior walls that separate the device into more than three compartments. In addition, the LED device 300 of FIG. 3D may include a variable wall thickness and internal radius to enhance structural strength and/or castellations 330, 331, 332, 333, 334, 335 having varying dimensions such as shown in FIG. 3B.

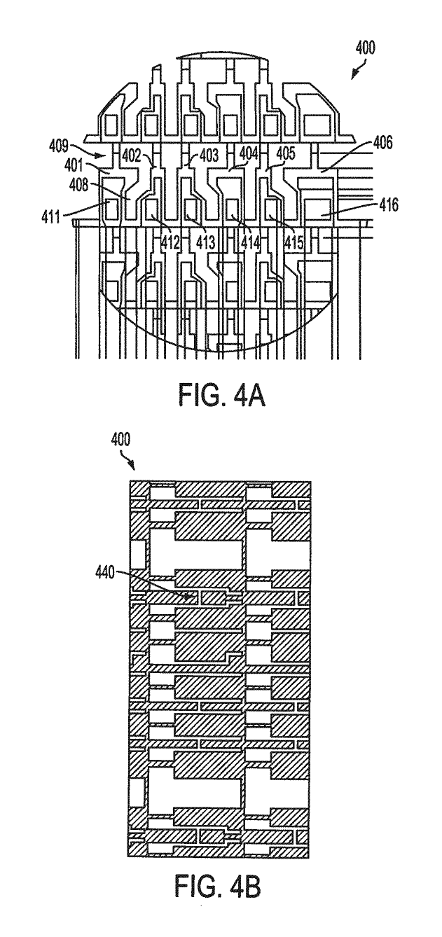

FIG. 4A is a schematic top (overhead) view of a lead frame 400 having a plurality of leads 401, 402, 403, 404, 405, 406 used for producing a packaged LED device, such as device 300. The lead frame 400 may be formed, for example, by patterning (e.g., etching) a copper sheet or plate to form the frame 400 and leads 401, 402, 403, 404, 405, 406 in a desired shape. Pits (i.e., recesses) 411, 412, 413, 414, 415, 416 may be formed in a surface of the leads 401, 402, 403, 404, 405, 406 to provide the recessed portions. The sides 408 and ends 409 of the leads 401, 402, 403, 404, 405, 406 may be etched to increase a surface area for the package material (e.g. epoxy) to mate with and thus improve the adhesion of the leads to the package. The leads may be removed from the frame 400 to produce a packaged LED device, as described further below.

FIG. 4B illustrates an alternative embodiment of a lead frame 400 having one or more “floating finger” leads 440 (i.e. a protrusion or finger that is not supported at both ends. e.g., which contains at least one free hanging, cantilevered end which is not attached to the frame). The floating finger lead frame may be made significantly wider to support it. The floating fingers allow for independent electrical connections inside the package after the leads are singulated (i.e., removed from the frame 400).

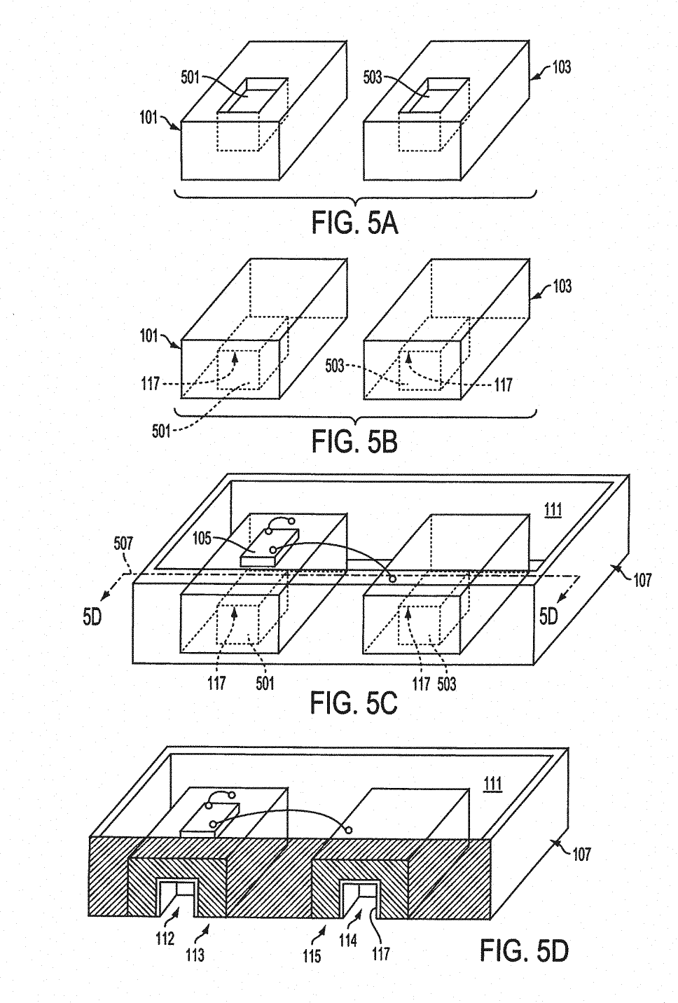

FIGS. 5A-D illustrate a method of packaging an LED die according to one embodiment. The method may include forming pits (i.e., recesses) 501, 503 in the back side of the respective leads 101, 103 of a lead frame, as shown in FIG. 5A. The leads frame having leads or “fingers” may be as shown in FIGS. 4A-B, for example. The leads 101, 103 are illustrated as rectangles for simplicity in FIGS. 5A-D, although other shapes may be used. In addition, the frame that connects the leads 101, 103 is not illustrated for clarity.

A metal filler 117 (e.g., a solderable metallization stack up) may be formed in the pits 501, 503, as shown in FIG. 5B. An LED die 105 may be bonded to the top surface of one or both leads 101, 103, as shown in FIG. 5C. The LED die 105 may be electrically connected to the leads 101, 103 by wires. The leads 101, 103 and LED die 105 may then be encapsulated by a package 107, which may be an epoxy material. The package 107 includes an opening 111 in its upper surface exposing at least the LED die 105.

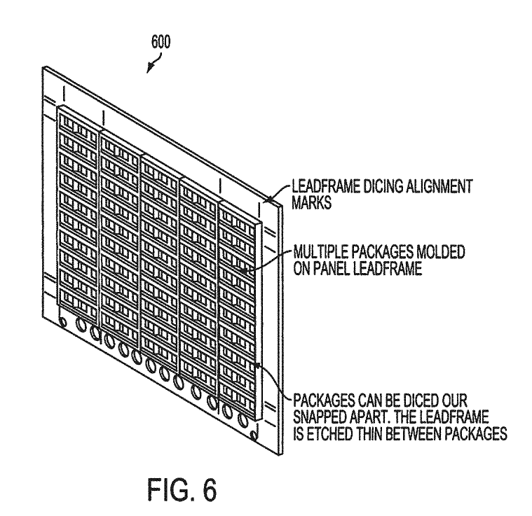

In embodiments, the package 107 may be formed by dipping a lead frame containing the leads 101, 103 and LED die(s) 105 into a mold containing an epoxy and solidifying the epoxy to form the package attached to the lead frame. Alternatively, the die 105 may be attached to the leads 101, 103 after the formation of the package 107 on the leads 101, 103. Thus, the LED die 105 may be electrically connected to the first lead and to the second lead by wire bonding the LED die to the first lead and to the second lead before or after the step of forming the package. A plurality of packages 107, each encapsulating a plurality of lead frame leads and one or more LED dies, may be formed over a lead frame 400 to form a panel 600 of packaged LEDs, as shown in FIG. 6. In embodiments, the molded panel 600 may have alignment marks (e.g., dicing lines) molded into the surface of the epoxy package walls. Similar marks, such as etched lines or slots, may be included in the lead frame 400. These features may facilitate inspection to check that the molded epoxy panel is aligned to the lead frame within specified tolerances. In addition, the alignment marks may aid a dicing operator in aligning a dicing saw blade to the panel and for quality assurance to check after dicing that the diced package walls are within tolerance. Thus, the singulation step may optionally include checking that a first alignment mark on the lead frame and a second alignment mark on the package (or on the panel) are within a predetermined tolerance, and aligning a dicing saw blade with the first alignment mark and the second alignment mark before dicing the package from the lead frame.

FIG. 5C illustrates a dicing line 507 in the epoxy package 107. The dicing line 507 may be aligned over the pits 501, 503 in the respective leads 101, 103 of the lead frame. The package 107 containing the LED die 105, the first lead 101 and the second lead 103 may then be separated from the lead frame, as shown in FIG. 5C. Separating the package 107 from the lead frame may include dicing or snapping the package along the dicing line 507 and through the pits 501, 503 to expose a first castellation 113 and a second castellation 115 in the side surface of the package 107. Dicing or otherwise separating the package 107 through the pits 501, 503 exposes the recessed portions 112, 114 of the leads 101, 103, as well as the filler material (e.g., solderable metal) which partially fills the pits.

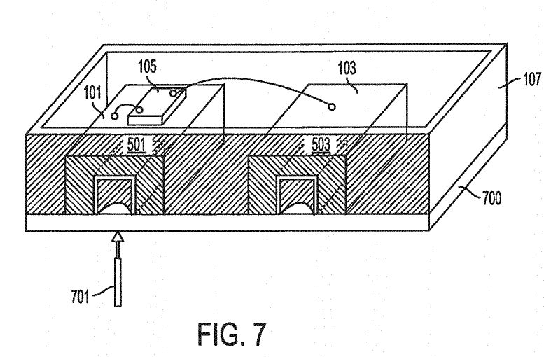

In embodiments, a dicing tape 700 may be bonded to the bottom surface of the package 107, prior to separating the package 107 from the lead frame (i.e., singulation), as shown in FIG. 7. The LED die 105 may be tested by poking a testing pin 701 or needle through the dicing tape 700 in the area of the pits 501, 503. The pits 501, 503 allow the tape 700 to stretch and the pin 701 to break through the tape to contact the leads 101, 103. The pin 701 may form a temporary electrical connection with the LED device to enable testing. This action of punching through tape instead of crushing or pinching has the added advantage that the probe tip is wiped clean and thus avoids clogging of the probe needle.

According to another aspect of the present disclosure, a packaged LED structure can be formed by providing a lead-containing mounting assembly, mounting LEDs on the lead-containing mounting assembly, and encapsulating the LEDs with a protective mold.

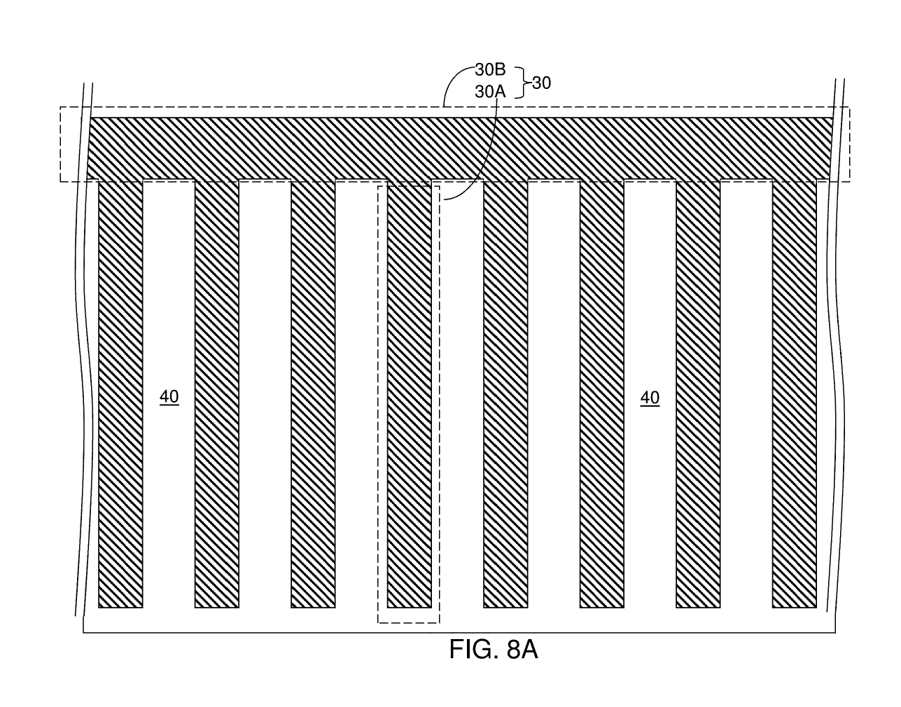

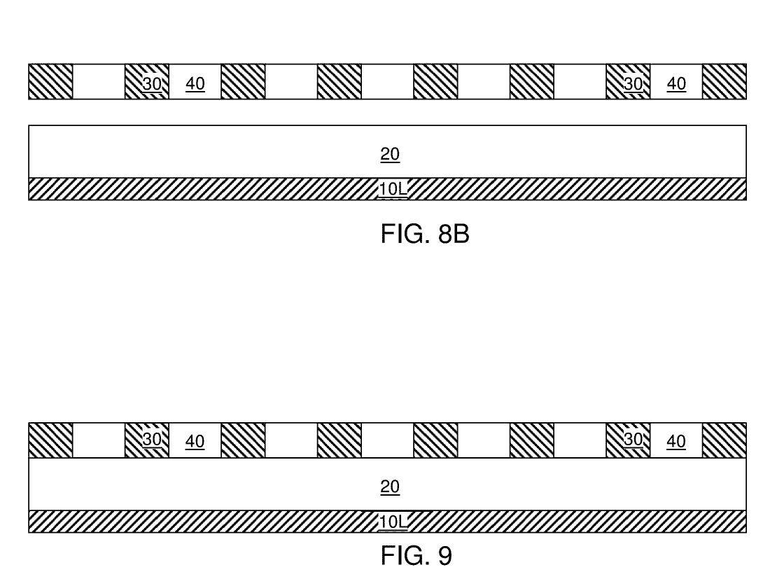

Referring to FIGS. 8A and 8B, an exemplary structure is illustrated, which includes a lead frame 30 overlying a layer stack of an insulating substrate 20 and a metal sheet 10L according to an embodiment of the present disclosure. The lead frame 30 can include a base bar portion 30B and a plurality of parallel fingers 30A extending from the base bar portion 30B. The lead frame 30 can include a metal such as gold, silver, copper, aluminum, or another metallic material. The lead frame 30 can be provided by patterning a metal sheet 10L. Insulating fingers 40 can be provided between neighboring pairs of the parallel fingers 30A of the lead frame 30. The insulating fingers 40 can be formed, for example, by providing the lead frame 30, applying an insulating material between the neighboring pairs of the parallel fingers 30A of the lead frame 30, and optionally removing the excess insulating material (for example, by polishing) from above a horizontal plane including the top surfaces of the lead frame 30 and from below a horizontal plane including the bottom surfaces of the lead frame 30. The insulating fingers 40 can include, for example, epoxy or another polymer material.

The insulating fingers 40 can be formed between neighboring pairs of parallel fingers 30A such that each of the insulating fingers 40 and the plurality of parallel fingers 30A of the lead frame 30 extends along a first direction; the insulating fingers 40 and the plurality of parallel fingers 30A alternate along a second direction that is perpendicular to the first direction; and the insulating fingers 40 and the plurality of parallel fingers 30A have surfaces located within a pair of parallel planes that are perpendicular to the first direction and the second direction. The pair of parallel planes can be the horizontal planes that include the top surfaces and the bottom surfaces of the insulating fingers 40 and the plurality of parallel fingers 30A.

The insulating substrate 20 can include a curable insulating polymer such as epoxy (e.g., pre-preg). For example, the curable insulating polymer of the insulating substrate 20 can be FR-4 glass epoxy that is typically employed to fabrication of printed circuit board.

The metal sheet 10L includes an elemental metal or an intermetallic alloy. For example, the metal sheet 10L can include copper or aluminum. The metal sheet 10L can be a blanket (unpatterned) sheet. The metal sheet 10L is formed directly on the backside surface of the insulating substrate 20 to form a layer stack of the insulating substrate 20 and the metal sheet 10L. The metal sheet 10L can be formed by deposition of a metal layer on the backside of the insulating substrate 20, for example, by physical vapor deposition (PVD), or by bonding a thin sheet of metal to the backside of the insulating layer. In one embodiment, the metal sheet 10L can include a copper foil.

Referring to FIG. 9, the lead frame 30 (and the insulating fingers 40) can be bonded to the layer stack of the insulating substrate 20 and a metal sheet 10L. For example, pressure can be applied to bond the lead frame 30 to the layer stack of the insulating substrate 20 and the metal sheet 10L. An anneal at an elevated temperature may be optionally employed while applying pressure between the lead frame 30 and the layer stack. The lead frame 30 is bonded to the side of the insulating substrate 20 opposite to the side contacting the metal sheet 10L.

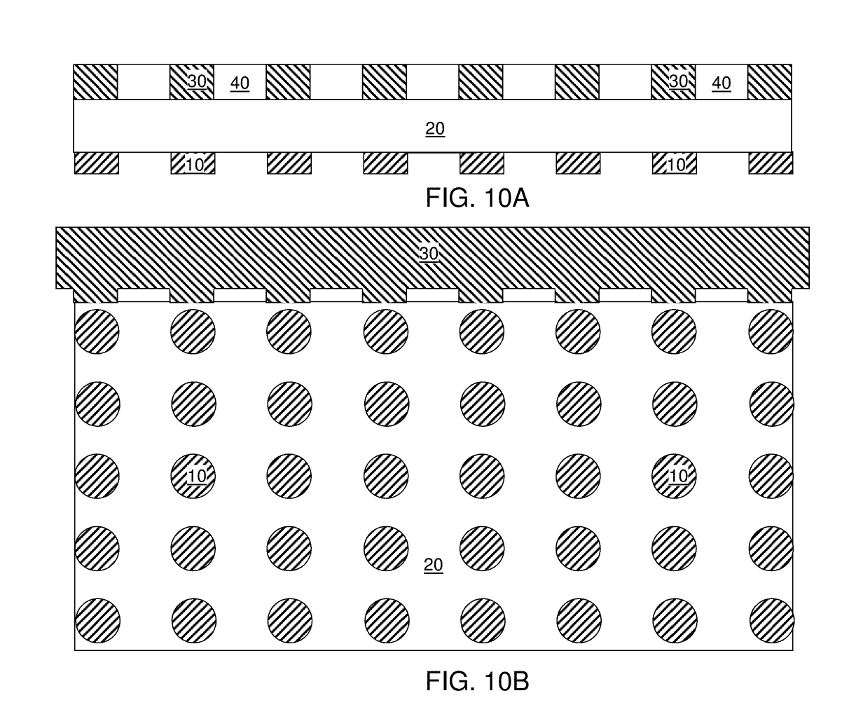

Referring to FIGS. 10A and 10B, the metal sheet 10L can be patterned into discrete metal plates 10 using any suitable metal patterning method. For example, a masking layer (such as a photoresist layer) can be applied to a physically exposed surface of the metal sheet 10L, and can be lithographically patterned to cover discrete areas. The exemplary structure may be flipped upside down during processing as needed. An etchant can be employed to remove physically exposed portions of the metal sheet 10L. For example, a wet etch process can be employed. The masking layer can be subsequently removed, for example, by ashing.

Each remaining portion of the metal sheet 10L constitutes a metal plate 10. The metal plates 10 can be arranged in a configuration of a two-dimensional array. Each metal plate 10 can underlie a finger 30A of the lead frame 30. This forms the printed circuit board, in which the insulating substrate 20 comprises the board and the metal plates 10 comprise the metal lines printed on the board. In one embodiment, the metal plates 10 can have circular or elliptical shapes.

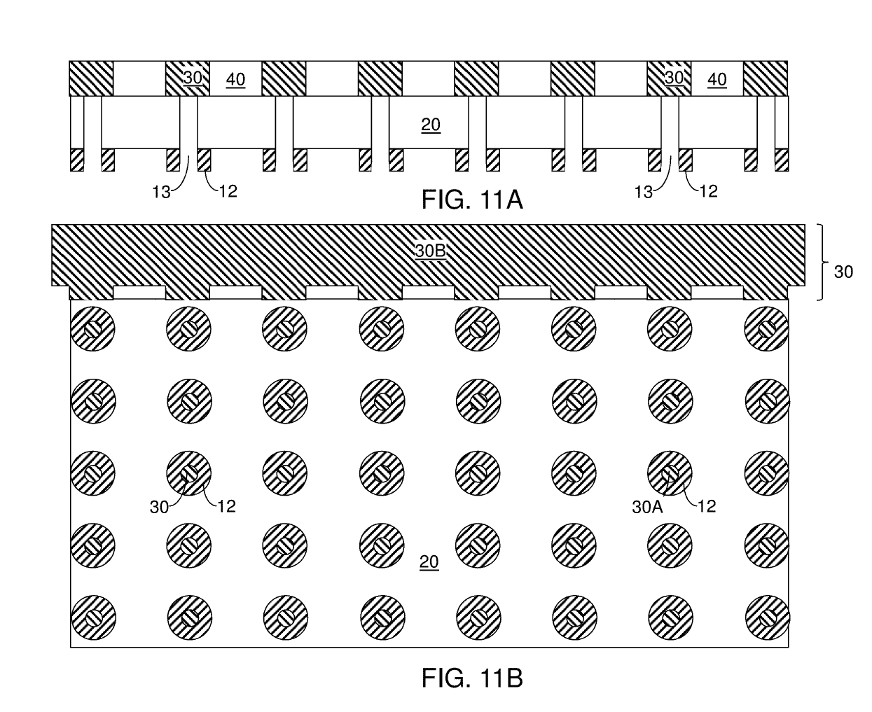

Referring to FIGS. 11A and 11B, a via cavity 13 is formed through a center portion of each metal plate 10 and a respective portion of the insulating substrate 20 that overlaps with the area of the via cavity 13. The remaining portion of each metal plate 10 is herein referred to as an annular metal plate 12. A horizontal surface of a finger 30A of a lead frame 30 is physically exposed at an end of each via cavity 13.

The via cavities 13 may be formed by drilling, a photolithographic process or any other patterning method. For example, a photoresist layer can be applied to cover the array of metal plates 10. The exemplary structure may be filliped upside down during processing as needed. Openings are formed through the photoresist layer by lithographic patterning such that each opening in the photoresist layer coincides with a center portion of a respective metal plate 10. An anisotropic etch is performed employing the patterned photoresist layer as an etch mask. The photoresist layer can be subsequently removed, for example, by ashing.

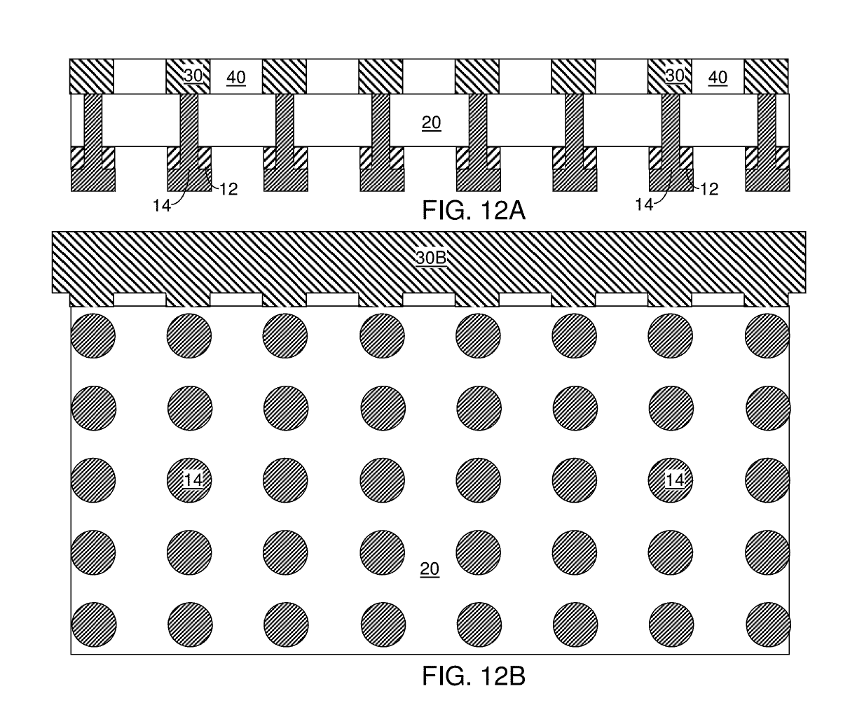

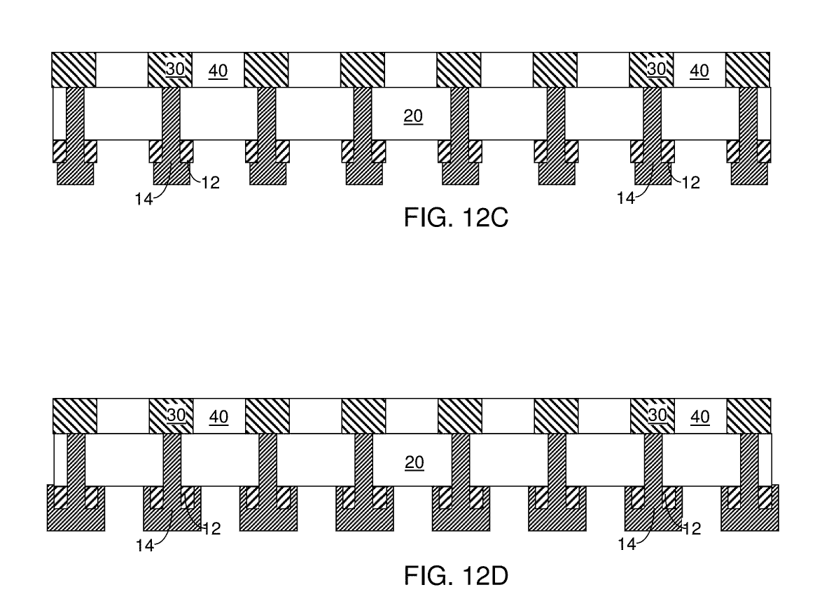

Referring to FIGS. 12A and 12B, a prototype castellation 14 is formed within each via cavity 13 by deposition of a metal therein. As used herein, a “prototype” element refers to an element that is subsequently modified to provide another structure. The base bar portion 30B of the lead frame 30 can extend past the insulating substrate 20 as shown in FIG. 12B or can be located on top of the insulating substrate 20. In one embodiment, the metal of the prototype castellations 14 can be deposited by physical vapor deposition, chemical vapor deposition, electroplating, electroless plating, or a combination thereof. In one embodiment, the prototype castellations 14 can be formed by non-selective deposition of a metal on remaining portions of the metal plates 10 (i.e., on the annular metal plates 12) and on surfaces of the lead frame 30 (e.g., on surfaces of the fingers 30A of the lead frame 30) that are exposed to the via cavities 13, and subsequent patterning of the metal that is deposited by the non-selective deposition method. Excess portions of the deposited metal can be removed, for example, by forming a patterned photoresist layer including patterned portions overlying, or underlying, each area within the annular metal plates 12, and removing portions of the deposited metal from areas not covered by the photoresist layer. The photoresist layer can be subsequently removed, for example, by ashing.

In another embodiment, selective deposition of a metal on surfaces of remaining portions of the metal plates 10 (i.e., the annular metal plates 12) and on surfaces (e.g., on surfaces of the fingers 30A) of the lead frame 30 that are exposed to the via cavities 13. For example, a metal plating process, such as electroless plating or electroplating that deposits a metallic material only on pre-existing metallic surfaces can be employed. In this case, the bottom surfaces of the lead frame 30 and the surfaces of the annular metal plates 12 can exposed to a plating solution, and in case electroplating is used, an electrical bias can be applied to the lead frame 30 and another electrode placed in the plating solution (contained in a plating bath). The upper surfaces and/or the sidewalls of the lead frame 30 may be masked with a dielectric material, or may be exposed to the plating solution. In this case, the prototype castellations 14 can be formed by selective growth from the bottom surfaces of the lead frame 30 and the surfaces of the annular metal plates 12. The dimensions of the cavities 13 may be optimized to facilitate formation of continuous prototype castellations 14.

FIGS. 12C and 12D are alternate embodiments of the exemplary structure after the processing steps of FIGS. 12A and 12B. Depending on the choice of deposition method and the optional patterning processes, the periphery of each prototype castellation 14 may be inside the periphery of an overlying annular metal portion 12, may coincide with the periphery of the overlying annular metal portion 12, or may be located outside the periphery of the overlying annular metal portion 12 (thereby completely covering the overlying annular metal portion 12).

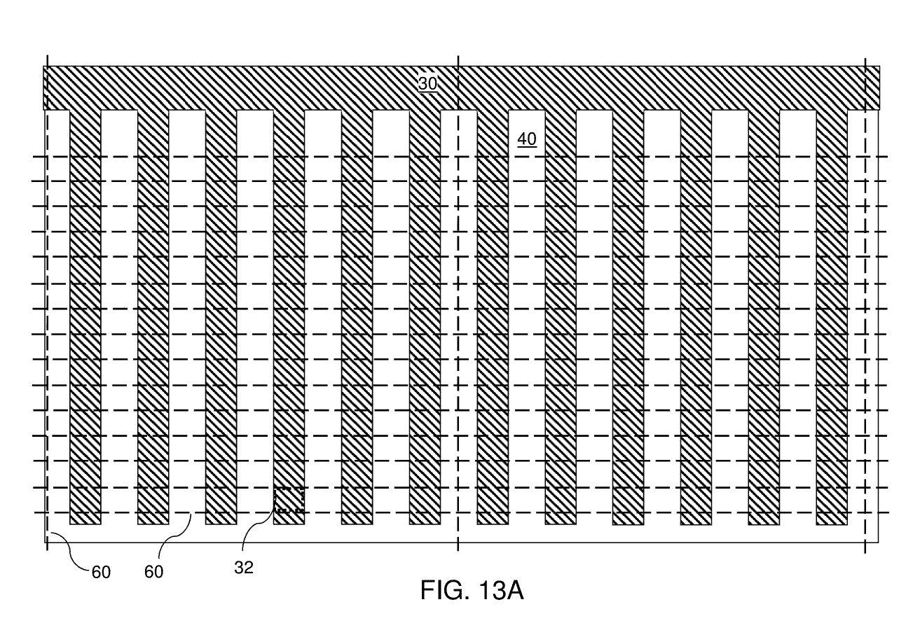

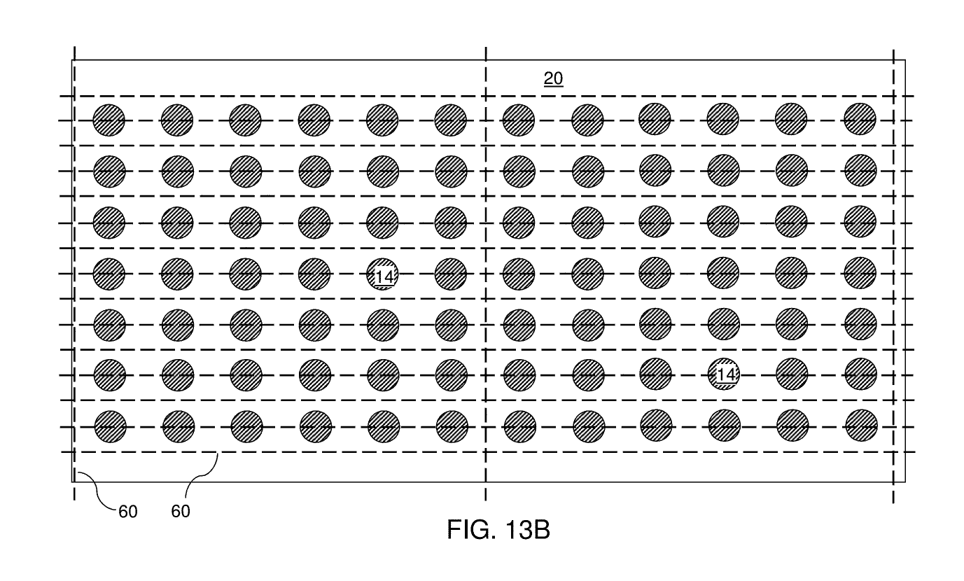

Referring to FIGS. 13A and 13B, the exemplary structure including the insulating substrate 20, the annular metal plates 12, the prototype castellations 14 within the via cavities 13 through the insulating substrate 20, and the lead frame 30 can be diced into lead-containing mounting structures along cut planes 60. Each of the lead-containing mounting structure includes a respective plurality of leads 32 that are remaining portions of the lead frame 30. In one embodiment, each lead-containing mounting structure includes a linear array of leads, each of which is a truncated portion of a finger 30A of the lead frame 30. The locations of the dicing channels can be selected such that each prototype castellation 14 is cut through, as shown in FIG. 13B. One prototype castellation forms two castellations 54. Thus, the remaining portion of each prototype castellation 14 includes a convex cylindrical surface contacting an insulating matrix (which is a diced portion of the insulating substrate 20), and a planar vertical surface which is a surface formed by dicing.

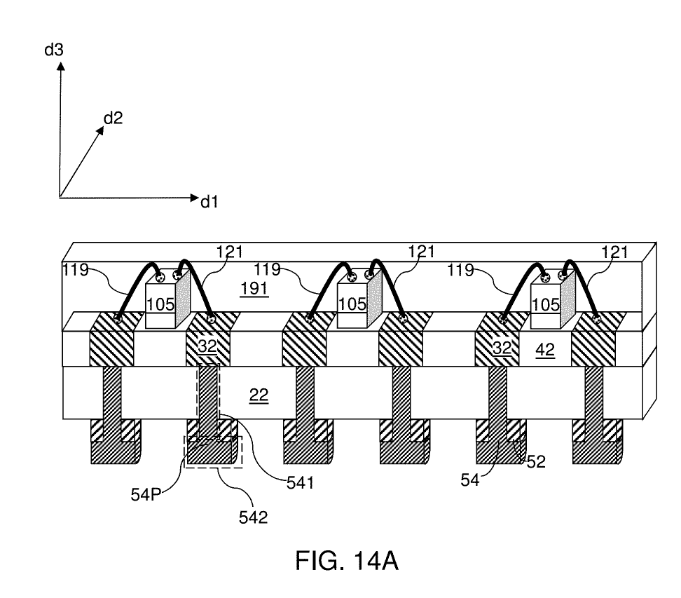

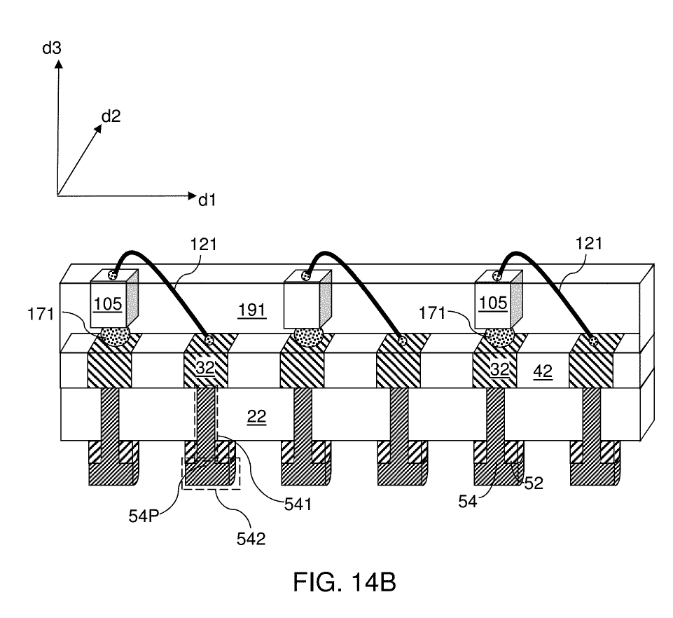

Referring to FIGS. 14A and 14B, each remaining portion of the fingers 30A of the lead frame 30 constitutes a lead 32. Each lead 32 can have a shape of a rectangular parallelepiped. Each remaining portion of the insulating fingers 40 constitutes an insulator portion 42. Each insulator portion 42 can have a shape of a rectangular parallelepiped. Each cut piece of the insulating substrate 20 constitutes an insulating matrix 22, which is an insulating strip. Each insulating matrix 22 can laterally extend along a lengthwise direction, which is herein referred to as a first direction d1, and can have a uniform width along a widthwise direction, which is herein referred to as a second direction d2. The surfaces of the rectangular parallelepipeds of the leads 32 and the insulator portions 42 can be perpendicular to the first direction d1, the second direction d2, or the third direction (e.g., vertical direction) d3.

Each cut portion of an annular metal plate 12 constitutes a semi-annular metal plate 52. Each cut portion of a prototype castellation 14 constitutes a castellation 54, which includes a planar physically exposed surface having a “T” shape (i.e., a combination of a wide rectangular end surface and a narrow rectangular surface abutting each other and laterally extending along perpendicular directions), a semi-elliptical or a semi-circular end surface, and a curved sidewall adjoining two edges of the wide rectangular end surface of the T-shaped surface. The T-shaped surface can be perpendicular to the second direction d2 (i.e., direction d2 is normal to this surface). The semi-elliptical or semi-circular end surface can be perpendicular to the third direction d3. Each lead-containing mounting structure (22, 32, 42, 52, 54) can include at least twice as many number of leads 32 as the total number of diodes 105 to be subsequently mounted thereupon.

In one embodiment, dicing of the assembly divides each prototype castellation 14 into two castellations 54 within a pair of lead-containing mounting structures. In one embodiment, dicing of the assembly divides each of the annular metal plates 12 into a pair of semi-annular metal plates 52 within in a respective pair of lead-containing mounting structures.

Light emitting diodes (LEDs) 105 can be mounted on a subset of the leads within a lead-containing mounting structure. In one embodiment, each LED 105 can be mounted on a lead 32 such that one node of the LED 105 is electrically shorted to the lead (e.g., using a first bonding wire 119 for a lateral LED, as shown in FIG. 14A, or a solder ball 171 that is bonded to the bottom electrode for a vertical LED, as shown in FIG. 14B), and a bonding wire 121 (or a second bonding wire 121 in case a first bonding wire 119 is employed) can be employed to connect to another lead 32 within the lead-containing mounting structure (22, 32, 42, 52, 54). A transparent encapsulation structure 191 can be formed over the mounted LEDs 105 and the lead-containing mounting structures (22, 32, 42, 52, 54).

The methods illustrated in FIGS. 8A-14B of the present disclosure illustrate a method of forming a high density mounting structure for mounting LEDs. The mounding structure includes leads therein at the time of mounting the LEDs. Because formation of the transparent encapsulation structure is the only remaining processing step after mounting the LEDs, the methods of the present disclosure can simplify the LED mounting process and can provide a high density LED configuration by disposing a plurality of lead-containing mounting structures in a display device.

According to an aspect of the present disclosure, a light emitting diode assembly is provided, which comprises: a lead-containing mounting structure (22, 32, 42, 52, 54) including a plurality of leads 32 located on a surface of an insulating matrix 22 and a plurality of castellations 54 partially embedded within the insulating matrix 22, wherein each of the leads 32 has a shape of a rectangular parallelepiped, and wherein each of the castellations 54 have a convex sidewall contacting the insulating matrix 22 and a planar surface 54P that is not in physical contact with the insulating matrix 22; a plurality of light emitting diodes 105 mounted on the plurality of leads 32, wherein two nodes of each of the light emitting diodes 105 are electrically shorted to a respective pair of leads 32 within the plurality of leads 32; and a transparent encapsulation structure 191 embedding the plurality of light emitting diodes 105 and mounted on the lead-containing mounting structure (22, 32, 42, 52, 54).

In one embodiment, each of the plurality of castellations 54 includes: a semi-cylindrical portion 541 extending through the insulating matrix 22; and a semi-circular or semi-elliptical cap portion 542 located on a backside surface of the insulating matrix 22. In one embodiment, the planar surfaces 54P of the plurality of castellations 54 and sidewalls of the plurality of leads 32 are within a same two-dimensional plane (e.g., a plane (d1, d3) containing the planar surfaces 54P of the plurality of castellations 54 formed by dicing). In one embodiment, sidewalls of the insulating matrix 22 are located between neighboring pairs of the plurality of castellations 54, and are located within the two-dimensional plane (d1, d3). In one embodiment, a plurality of semi-annular metal plates 52 may be provided. Each of the semi-annular metal plates 52 can be located between the insulating matrix 22 and a respective one of the semi-circular or semi-elliptical cap portions 542.

In one embodiment, the plurality of leads 32 can be arranged along a first direction d1; and a plurality of insulator portions 42 is arranged along the first direction d1 and is interlaced with the plurality of leads 32. In one embodiment, the insulating matrix 22 laterally extends along the first direction d1; and the plurality of leads 32, the plurality of insulator portions 42, and the insulating matrix 22 have a same thickness along a second direction d2 that is perpendicular to the first direction d1. In one embodiment, each of the plurality of castellations 54 has a lesser extent along the second direction d2 (i.e., the distance between a planar surface 54P and a portion of the castellation 54 that protrude along the second direction d2) than the thickness of the plurality of leads 32, the plurality of insulator portions 42, and the insulating matrix 22 (which is the same as the distance between adjacent dicing channels in direction d2). In one embodiment, the planar surface 54P is perpendicular to the second direction d2 (i.e., direction d2 is normal to plane 54P); and the convex sidewall (i.e., the interface between the semi-cylindrical portion 541 and the insulating matrix 22) extends along a third direction d3 that is perpendicular to the first and second directions (d1, d2) with a same cross-sectional shape within planes (d1, d2) that are perpendicular to the third direction d3 (i.e., with a cross-sectional shape that is invariant under translation along the third direction d3).

In one embodiment, each of the plurality of light emitting diodes 105 includes a first node that is electrically shorted to one of the plurality of leads 32 by a bonding wire 121, and a second node that is electrically shorted to another of the plurality of leads 32 by a solder ball 171 or another bonding wire 119. In one embodiment, the plurality of light emitting diodes 105 comprise red, green and blue light emitting diodes which after being mounted on the lead-containing mounting structures can be used as a light bar for a backlight of a display device, such as a liquid crystal display device.

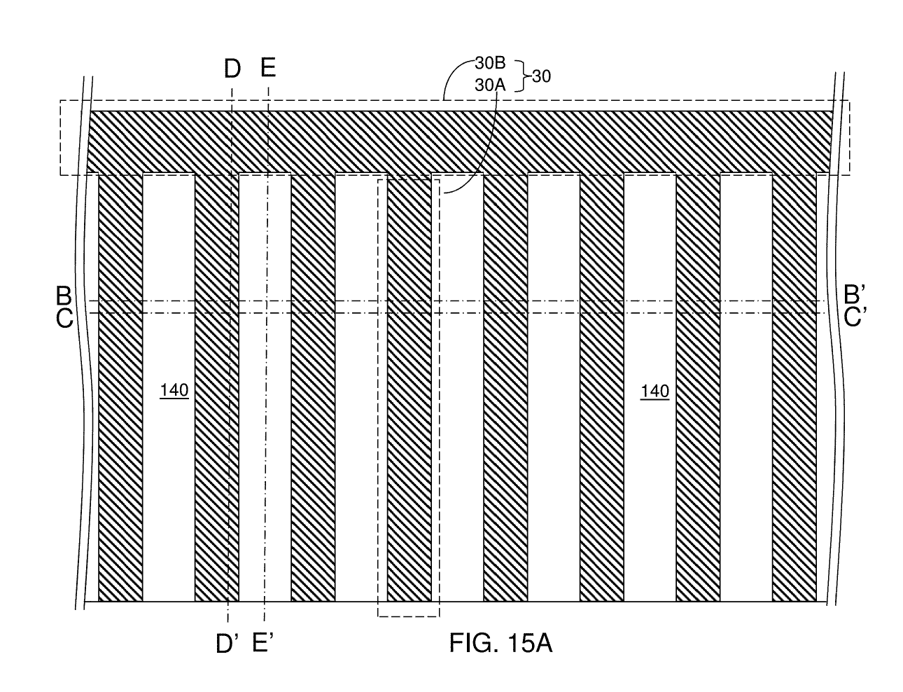

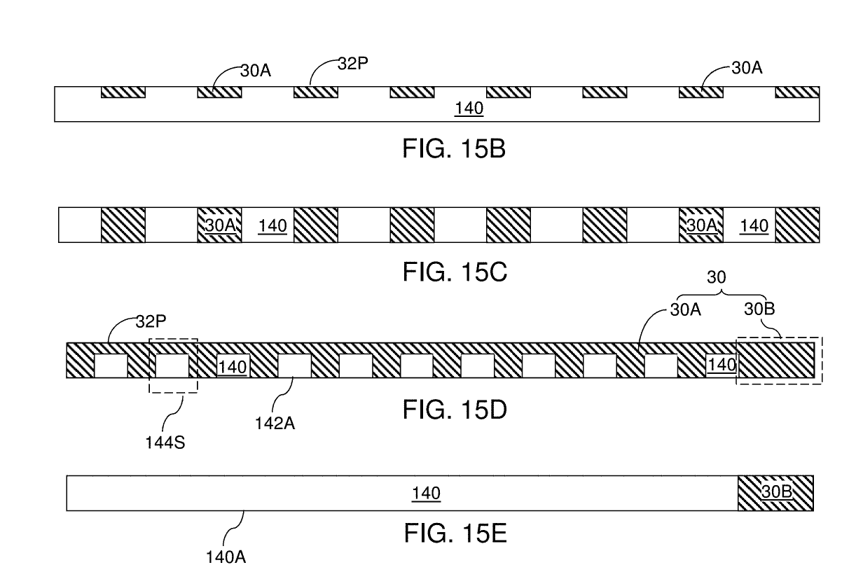

Referring to FIGS. 15A-15E, another exemplary structure according to another embodiment of the present disclosure is illustrated, which includes an assembly of a lead frame 30 and insulating fingers 140, but without necessarily insulating the underlying insulating matrix 22. In this embodiment, the insulating fingers located between the fingers 30A of the lead frame 30 comprise an insulating fingered-matrix 140. As used herein, a “fingered-matrix” refers to matrix including multiple fingers. The insulating fingered-matrix 140 is a continuous insulating material portion that includes insulating fingers 140A (one of which is shown in FIG. 15E) as in the exemplary structure illustrated in FIGS. 8A and 8B. In addition, the insulating fingered-matrix 140 includes a two-dimensional periodic array of connecting insulator portions 142A (a subset of which is shown in FIG. 15D) that connects neighboring pairs of insulating fingers 140A. The thickness of the connecting insulator portions is less than the thickness of the insulating fingers, and the back side surface of the connecting insulator portions can be within a same horizontal plane as the back side surfaces of the insulating fingers. For example, the thickness of the connecting insulator portions can be in a range from 10% to 98%, such as from 50% to 90%, of the thickness (e.g., height) of the insulating fingers. The fingers 30A of the lead frame 30 can be provided by patterning a metal sheet 10L with indentations (e.g., side facing castellations 144S) followed by molding the lead frame with an epoxy or silicon molding compound to form the insulating fingered-matrix 140. The side facing castellations 144S match the profiles of the connecting insulator portions 142A of the insulating fingered-matrix 140.

The lead frame 30 can include a base bar portion 30B and a plurality of parallel fingers 30A extending from the base bar portion 30B. Alternatively, the lead frame 30 can be formed without the base bar portion 30B, i.e., as a plurality of discrete fingers 30A that can be snapped into the grooves in the insulating fingered-matrix 140. The lead frame 30 can include a metal such as gold, silver, copper, aluminum, or another metallic material. While the insulating fingers illustrated in FIGS. 8A and 8B have a uniform thickness, the insulating fingers illustrated in FIGS. 15A-15E have an undulating thickness profile along the lengthwise direction of each of the parallel fingers 30A. The maximum thickness of each finger 30A of the lead frame 30 can be about the same, or the same, as the thickness of the insulating fingers of the insulating fingered-matrix 140. The minimum thickness of each finger 30A can be substantially the same, or the same, as the difference between the thickness of the insulating fingers of the insulating fingered-matrix 140 and the thickness of the connecting insulator portions of the insulating fingered-matrix 140. The insulating fingered-matrix 140 can include, for example, silicon, epoxy or another polymer material. The matrix 140 can include a white color material with an optional silver colored plating for enhanced reflectivity.

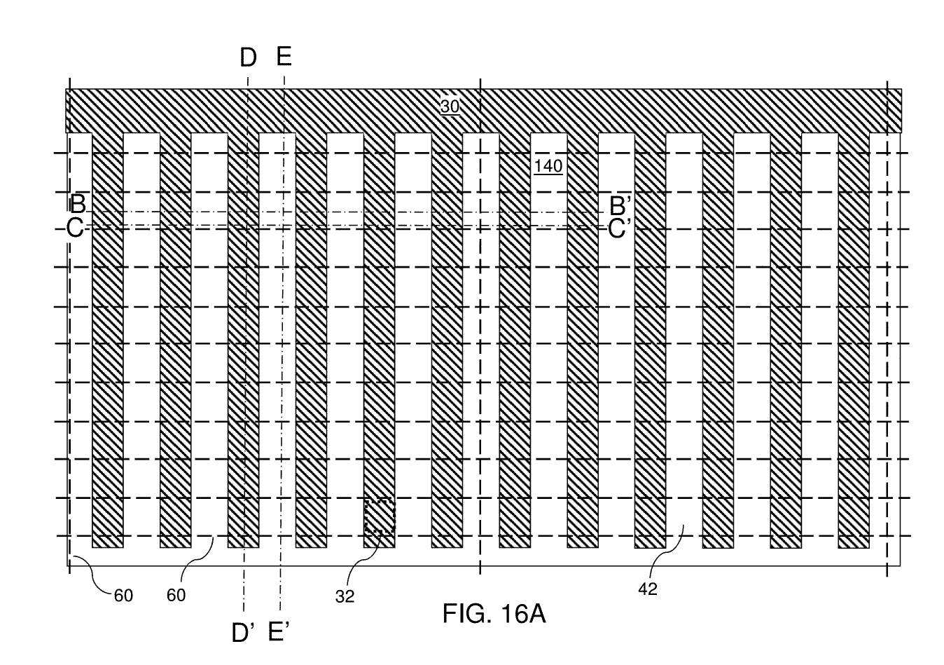

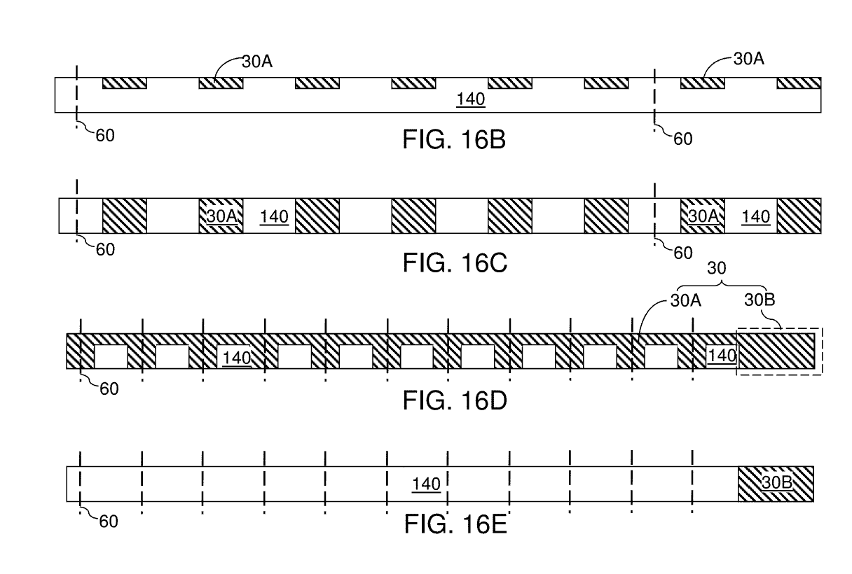

Referring to FIGS. 16A and 16B, the exemplary structure including the insulating fingered matrix 140 and the lead frame 30 can be diced into lead-containing mounting structures along cut planes 60. Each of the lead-containing mounting structure includes a respective plurality of leads 32 that are remaining portions of the lead frame 30. In one embodiment, each lead-containing mounting structure includes a linear array of leads 32, each of which is a truncated portion of a finger 30A of the lead frame 30. In one embodiment, the locations of the dicing channels can be selected such that thick portions of the fingers 30A of the lead frame 30 are diced through. In one embodiment, each lead 32 can include a pair of castellations, which are vertically protruding portions of the lead 32. The pair of castellations 144S can be connected to each other by a pad portion 32P of the lead 32, which can function as a landing pad for mounting of light emitting diodes in some embodiments. In this embodiment, each castellation 144S can be a side facing castellation comprising two metal prongs extending away from the pad portion 32P and separated from each other by a recess, similar to a battlement.

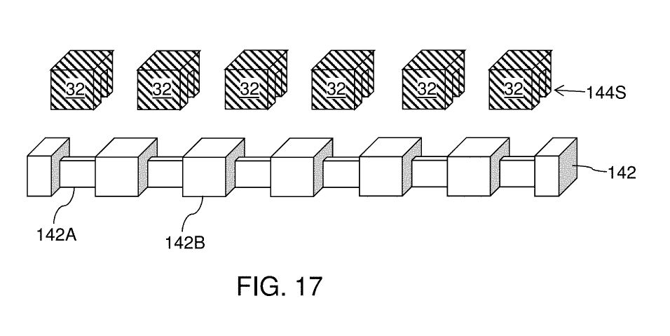

FIG. 17 shows an exploded three dimensional view of a lead-containing mounting structure (32, 142), which includes an insulating strip 142 having an undulating height and having an undulating width. As used herein, a dimension is “undulating” if the dimension increases and decreases with translation along a lengthwise direction of an object. The insulating strip 142 is a continuous insulating material strip comprised of alternating thinner connecting insulator portions 142A and thicker separator insulator portions 142B which are both made of an electrically insulating material. Each lead 32 can have a pad portion 32P having a planar surface and a pair of castellations 144S that protrude downward from the pad portion 32P over the connecting insulator portions 142A. A respective separator insulator portion 142B is located between each pair of leads 32. In one embodiment, each of the pair of castellations 144S can have a vertical planar surface.

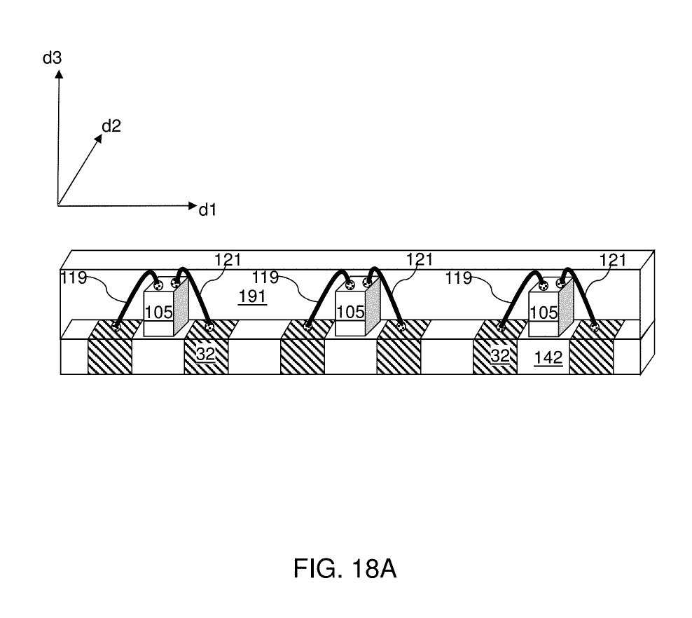

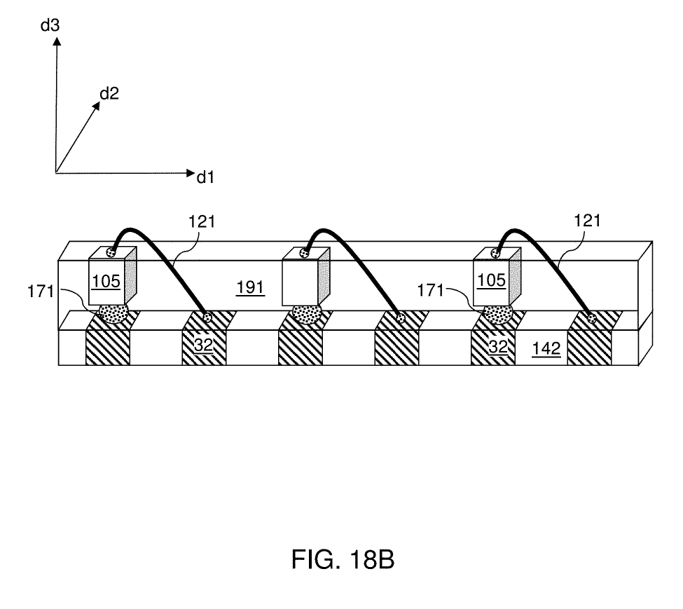

Referring to FIGS. 18A and 18B, light emitting diodes (LEDs) 105 can be mounted on a subset of the leads 32 within a lead-containing mounting structure. In one embodiment, each LED 105 can be mounted on a lead 32 (e.g., on the pad portion 32P) such that one node of the LED 105 is electrically shorted to the lead (e.g., using a first bonding wire 119 for a lateral LED, as shown in FIG. 18A, or a solder ball 171 that is bonded to the bottom electrode for a vertical LED, as shown in FIG. 18B), and a bonding wire 121 (or a second bonding wire 121 in case a first bonding wire 119 is employed) can be employed to connect to another lead 32 within the lead-containing mounting structure (32, 142). A transparent encapsulation structure 191 can be formed over the mounted LEDs 105 and the lead-containing mounting structures (32, 142).

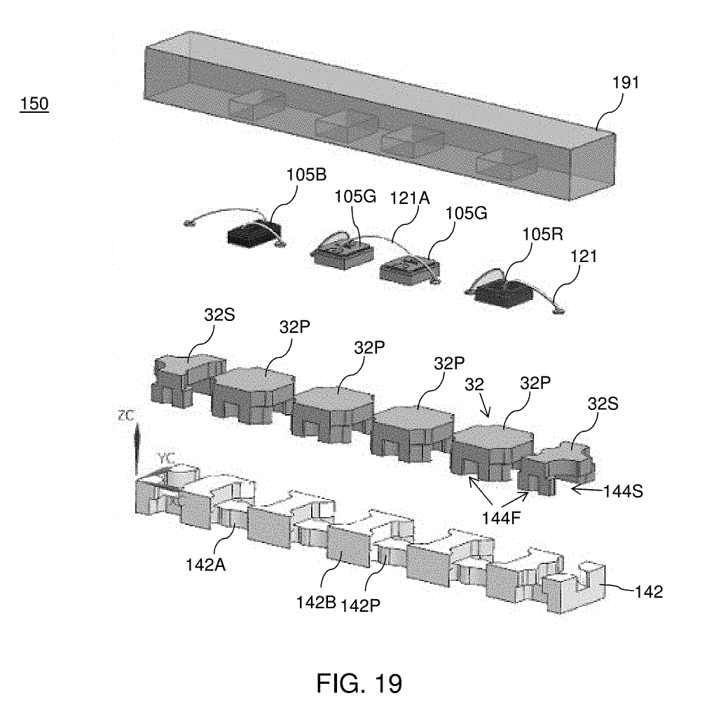

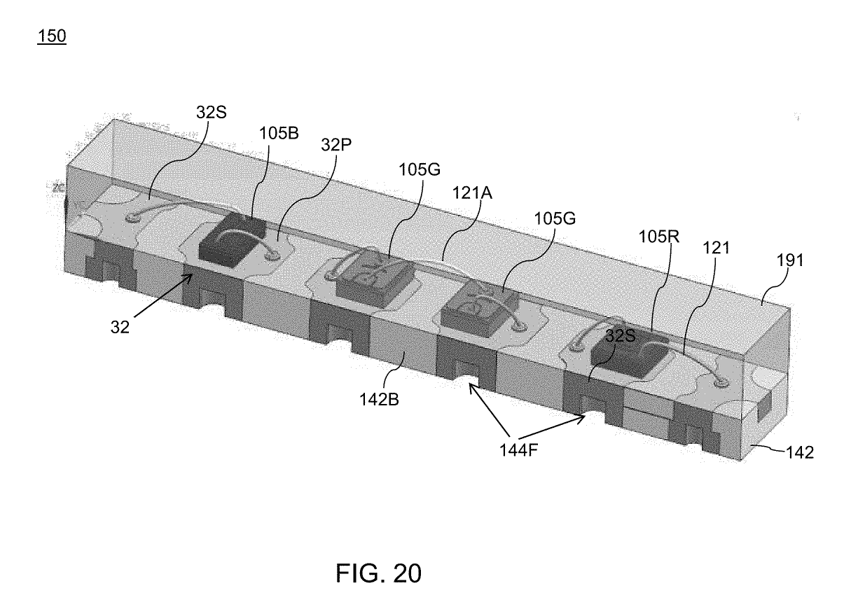

FIGS. 19 and 20 show an exploded three dimensional view and a perspective three dimensional view, respectively, of a LED package 150 of an alternative embodiment. In this embodiment, the package 150 is similar to the structure shown in FIGS. 15A to 18B. However, the structure of this alternative embodiment contains front facing castellations 144F in addition to the side facing castellations 144S, which are rotated by 90 degrees from the front facing castellations 144F.

In this alternative embodiment, the connecting insulator portions 142A are located in the grooves in the respective side facing castellations 144S as in the previous embodiment. However, the connecting insulator portions 142A also contain protrusions 142P which extend into the respective front facing castellations 144F.

The package 150 shown in FIGS. 19 and 20 can be a packaged light bar that includes four LEDs 105, such as a blue light emitting LED 105B, two green light emitting LEDs 105G and a red light emitting LED 105R, and six leads 32. However, any number of LEDs and any suitable color LEDs 105 may be used. The green light emitting LEDs 105G may be connected to each other by a lead 121A. Each of the four LEDs 105 is located on and is electrically connected to a respective one of four pad portions 32P of a respective supporting lead 32. The structure also includes two additional side leads 32S which are electrically connected to the respective blue and red LEDs (105B, 105R) and have a different configuration (e.g., different shape) from that of the supporting leads 32.

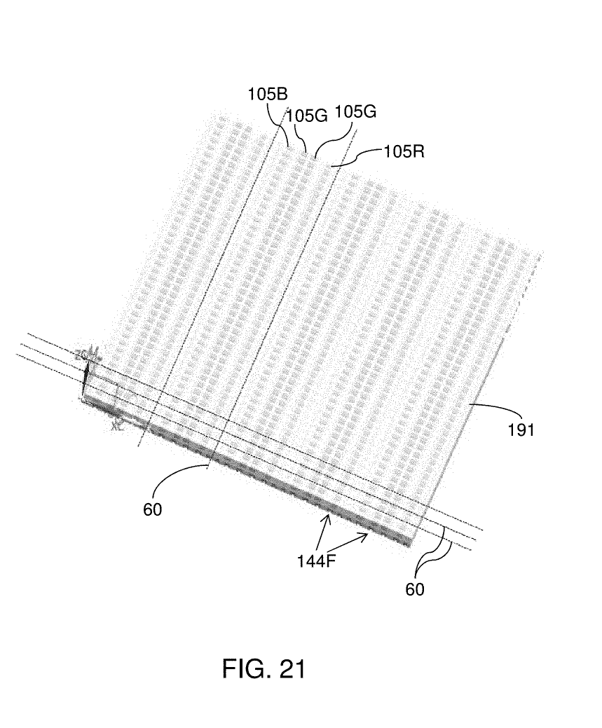

The structure shown in FIGS. 19 and 20 may be formed similar to the method described above with respect to FIGS. 15A to 18B. In this embodiment, the lead frame 30 contains front and side castellations (144F, 144S). The lead frame is molded with a resin (e.g., epoxy or silicone molding compound) to form a resin molded lead frame, followed by bonding (e.g., wire bonding) LED 105 die to the exposed leads in the resin molded lead frame, and followed forming a transparent encapsulation structure 191 embedding the plurality of LEDs 105. The encapsulated structure is then diced along the cut planes 60, as shown in FIG. 21 to form multi-color LED packages 150, such as an RGB light bar which emits white light which comprises a mixture of red, green and blue light.

The methods illustrated in FIGS. 15A-21 of the present disclosure illustrate a method of forming a high density mounting structure for mounting LEDs. The mounting structure includes leads therein at the time of mounting the LEDs. Because formation of the transparent encapsulation structure is the only remaining processing step after mounting the LEDs, the methods of the present disclosure can simplify the LED mounting process and can provide a high density LED configuration by disposing a plurality of lead-containing mounting structures in a display device.

According to an aspect of the present disclosure, a method of packaging light emitting diodes (LEDs) 105 includes molding a lead frame 30 comprising a plurality of lead frame fingers 30A that are parallel to each other such that the lead frame fingers are separated from each other by a molded insulating structure (42, 142) to form a molded lead frame, mounting light emitting diodes 105 to at least a portion of the molded lead frame, and dicing the molded lead frame to form a plurality of lead-containing mounting structures{(22, 32, 42, 52, 54) or (32, 142)}, wherein each of the lead-containing mounting structure includes a respective plurality of leads 32 that are remaining portions of the lead frame, and wherein each of the plurality of leads contains at least one castellation (54, 144S, 144F).

In one embodiment, each of the plurality of leads 32 contains a front castellation 144F and a side castellation 144S located under a pad portion 32P, where the front castellation is rotated by 90 degrees from the side castellation. The front castellation 144F is at least partially unfilled while the side castellation 144S is completely filled with a connecting insulator portion 142A of the insulating structure 142.

In one embodiment, the light emitting diodes can be encapsulated in a transparent encapsulation structure 191 after the step of mounting the light emitting diodes 105. The insulating structure 142 can be a reflective structure. The step of dicing can occur after the steps of mounting and encapsulating. The molded lead frame can have a planar upper surface comprising the pad portions 32P of the leads 32 and the insulating structure 142 (e.g., the co-planar top surface of pad portions 32P and portions 142B of structure 142. The light emitting diodes 105 are mounted on the pad portions 32P and electrically connected to the pad portions 32P prior to the step of encapsulating.

In another embodiment, the insulating structure comprises an insulating fingered-matrix 140 including a one-dimensional array of insulating fingers that extend along a same direction and a two-dimensional periodic array of connecting insulator portions that connect neighboring pairs of insulating fingers. In one embodiment, the plurality of parallel fingers 30A of the lead frame 30 has an undulating thickness (as illustrated in FIG. 15B) along a lengthwise direction of each finger. In one embodiment, the plurality of parallel fingers 30A has a maximum thickness that is the same as a thickness of the insulating fingers and a minimum thickness that is the same as a difference between the thickness of the insulating fingers and a thickness of the connecting insulator portions.

In one embodiment, the lead frame 30 comprises a base bar portion 30B and a plurality of parallel fingers 30A that extend from the base bar portion 30A. In one embodiment, the insulating fingers and the plurality of parallel fingers 30A are formed such that: each of the insulating fingers and the plurality of parallel fingers 30A extends along a first direction (e.g., the direction perpendicular to the plane B-B′ in FIG. 15A); the insulating fingers and the plurality of parallel fingers 30A alternate along a second direction (e.g., the direction perpendicular to the plane D-D′ in FIG. 15A) the direction that is perpendicular to the first direction; and the insulating fingers and the plurality of parallel fingers 30A have surfaces located within a pair of parallel planes that are perpendicular to the first direction and the second direction (e.g., the planes of top surfaces and bottom surfaces shown in FIGS. 15B-15D).

In one embodiment, each of the plurality of lead-containing mounting structures includes a plurality of leads 32 arranged along a first direction d1; each lead 32 among the plurality of leads includes a first planar surface (e.g., perpendicular to the third direction d3) and a second planar surface (e.g., perpendicular to the second direction d2) having different surface normal directions, each of the different surface normal directions being perpendicular to the first direction d1.

According to an embodiment of the present disclosure, a light emitting diode assembly is provided, which comprises: a lead-containing mounting structure {(22, 32, 42, 52, 54) or (32, 142)} including a plurality of leads 32 located on an insulating structure {(22 and/or 42) or 142} that extend along a first direction d1 and having sidewalls contained within a pair of planes that extend along the first direction d1 and perpendicular to a second direction d2, wherein the plurality of leads 32 are laterally spaced apart along the first direction d1, and are attached to the insulating structure {(22 and/or 42) or 142}. In one embodiment, the lead-containing mounting structure comprising a plurality of castellation (54, 144F, 144S) containing leads 32 separated by a reflective insulating structure 142 along a first direction d1 and having a planar top surface and sidewalls contained within a pair of planes that extend along the first direction d1.

A plurality of light emitting diodes 105 are mounted on the plurality of leads 32, wherein two nodes of each of the light emitting diodes 105 are electrically shorted to a respective pair of leads 32 within the plurality of leads. A transparent encapsulation structure 191 embedding the plurality of light emitting diodes 105 is provided over the lead-containing mounting structure {(22, 32, 42, 52, 54) or (32, 142)}.

In one embodiment, the insulating structure 142 is a continuous insulating material portion having an undulating width in a second direction d2 that changes as a function of a distance along the first direction d1. In one embodiment, the insulating structure 142 has an undulating height along a third direction d3 that is perpendicular to the first direction d1 and the second direction d2, wherein the undulating height changes as a function of a distance along the first direction d1. In one embodiment, each of the plurality of leads 32 has a thickness along the second direction d2 that is the same as a maximum of the undulating width of the continuous insulating material portion.

In one embodiment, each of the plurality of leads 32 has a pad 32P portion having a planar surface (which can be perpendicular to the third direction d3) and a pair of side castellations 144S that extend from the pad portion along a direction that is perpendicular to the planar surface (e.g., along the third direction d3). In one embodiment, a connecting insulator portion 142A of the continuous insulating material portion 142 is located between the pair of castellations for each lead 32 of the plurality of leads.

In the embodiment shown in FIGS. 19-21, each of the plurality of leads 32 further comprises a front castellation 144F located under the pad portion 32P. The front castellation 144F is rotated by 90 degrees from the pair of side castellations 144S. The front castellation is at least partially unfilled while the side castellation is filled with a connecting insulator portion 142A of the insulating structure 142.

A transparent encapsulation structure 191 can be located over the plurality of light emitting diodes 105. In one embodiment, a first node of one of the light emitting diodes 105 is electrically shorted to one of the plurality of leads 32 by a first bonding wire 119; and a second node of the one of the light emitting diodes 105 is electrically shorted to another of the plurality of leads 32 by a second bonding wire 121. Alternatively, a first node of one of the light emitting diodes 105 is electrically shorted to one of the plurality of leads 32 by a bonding wire 121; and a second node of the one of the light emitting diodes 105 is electrically shorted to another of the plurality of leads 32 by a solder ball 171.

The foregoing method descriptions are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not necessarily intended to limit the order of the steps; these words may be used to guide the reader through the description of the methods. Further, any reference to claim elements in the singular, for example, using the articles “a,” “an” or “the” is not to be construed as limiting the element to the singular.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A method of packaging light emitting diodes (LEDs), comprising:
molding a lead frame comprising a plurality of lead frame fingers that are parallel to each other such that the lead frame fingers are separated from each other by a molded insulating structure to form a molded lead frame;
mounting light emitting diodes to at least a portion of the molded lead frame; and
dicing the molded lead frame to form a plurality of lead-containing mounting structures, wherein each of the lead-containing mounting structure includes a respective plurality of leads that are remaining portions of the lead frame, and wherein each of the plurality of leads contains at least one castellation.

2. The method of claim 1, wherein each lead frame finger has an undulating thickness along a lengthwise direction of each finger.

3. The method of claim 2, wherein:
each of the plurality of leads contains a front castellation and a side castellation located under a pad portion;
the front castellation is rotated by 90 degrees from the side castellation;
the front castellation is at least partially unfilled; and
the side castellation is filled with a connecting insulator portion of the insulating structure.

4. The method of claim 2, further comprising encapsulating the light emitting diodes in a transparent encapsulation structure after the step of mounting the light emitting diodes.

5. The method of claim 4, wherein:
the insulating structure is a reflective structure;
the step of dicing occurs after the steps of mounting and encapsulating;
the molded lead frame has a planar upper surface comprising the pad portions of the leads and the insulating structure; and
the light emitting diodes are mounted on the pad portions and electrically connected to the pad portions prior to the step of encapsulating.

6. The method of claim 2, wherein:
the insulating structure comprises an insulating fingered-matrix including a one-dimensional array of insulating fingers that extend along a same direction and a two-dimensional periodic array of connecting insulator portions that connect neighboring pairs of insulating fingers;
the plurality of parallel fingers has a maximum thickness that is the same as a thickness of the insulating fingers and a minimum thickness that is the same as a difference between the thickness of the insulating fingers and a thickness of the connecting insulator portions; and
the lead frame comprises a base bar portion and the plurality of fingers that extend from the base bar portion.

7. The method of claim 6, wherein the insulating fingers and the plurality of parallel fingers are formed such that:
each of the insulating fingers and the plurality of parallel fingers extends along a first direction;
the insulating fingers and the plurality of parallel fingers alternate along a second direction that is perpendicular to the first direction; and
the insulating fingers and the plurality of parallel fingers have surfaces located within a pair of parallel planes that are perpendicular to the first direction and the second direction.

8. The method of claim 1, wherein:
each of the plurality of lead-containing mounting structures includes a plurality of leads arranged along a first direction; and
each lead among the plurality of leads includes a first planar surface and a second planar surface having different surface normal directions, each of the different surface normal directions being perpendicular to the first direction.

9. The method of claim 1, further comprising:
bonding the lead frame to a layer stack of an insulating substrate and a metal sheet;
patterning the metal sheet into metal plates;
forming a via cavity through each metal plate into the insulating substrate, wherein a surface of a respective lead frame is exposed at an end of each via cavity; and
forming a prototype castellation comprising a metal within each via cavity prior to the step of dicing.

10. The method of claim 1, wherein:
a first node of one of the light emitting diodes is electrically shorted to one of the plurality of leads by a bonding wire; and
a second node of the one of the light emitting diodes is electrically shorted to another of the plurality of leads by a solder ball or by a second bonding wire.

11. A light emitting diode assembly comprising:
a lead-containing mounting structure comprising a plurality of castellation containing leads separated by a reflective insulating structure along a first direction and having a planar top surface and sidewalls contained within a pair of planes that extend along the first direction;
a plurality of light emitting diodes mounted on the plurality of leads, wherein two nodes of each of the light emitting diodes are electrically shorted to a respective pair of leads within the plurality of leads; and
a transparent encapsulation structure embedding the plurality of light emitting diodes.

12. The light emitting diode assembly of claim 11, wherein the insulating structure is a continuous insulating material portion having an undulating width in a second direction that changes as a function of a distance along the first direction.

13. The light emitting diode assembly of claim 12, wherein the insulating structure has an undulating height along a third direction that is perpendicular to the first direction and the second direction, wherein the undulating height changes as a function of a distance along the first direction.

14. The light emitting diode assembly of claim 13, wherein each of the plurality of leads has a thickness along the second direction that is the same as a maximum of the undulating width of the continuous insulating material portion.

15. The light emitting diode assembly of claim 11, wherein each of the plurality of leads has a pad portion having a planar top surface and a pair of side castellations that extend from the pad portion along a direction that is perpendicular to the planar surface.

16. The light emitting diode assembly of claim 15, wherein:
each of the plurality of leads further comprises a front castellation located under a pad portion;
the front castellation is rotated by 90 degrees from the pair of side castellations;
the front castellation is at least partially unfilled; and
the side castellation is filled with a connecting insulator portion of the insulating structure.

17. The light emitting diode assembly of claim 11, wherein the assembly comprises a packaged light bar containing one blue light emitting LED, two green light emitting LEDs and one red light emitting LEDs located on and electrically connected to one of four respective supporting leads of the light bar.

18. The light emitting diode assembly of claim 11, wherein the two green light emitting LEDs are electrically connected to each other by a lead, and wherein the blue light emitting LED and the red light emitting LED are electrically connected to side leads having a different configuration from each the four supporting leads.

19. The light emitting diode assembly of claim 11, wherein:
a first node of one of the light emitting diodes is electrically shorted to one of the plurality of leads by a first bonding wire; and
a second node of the one of the light emitting diodes is electrically shorted to another of the plurality of leads by a second bonding wire.

20. The light emitting diode assembly of claim 11, wherein:
a first node of one of the light emitting diodes is electrically shorted to one of the plurality of leads by a bonding wire; and
a second node of the one of the light emitting diodes is electrically shorted to another of the plurality of leads by a solder ball.
